(19) United States
(12) Patent Application Publication
(10) Pub. No.: US 2025/0078920 A1
(43) Pub. Date: Mar. 6, 2025

(54) DIGITAL PHASE SOURCE FOR JOSEPHSON JUNCTION COMPUTING

(71) Applicant: SeeQC, Inc., Elmsford, NY (US)

(72) Inventors: Federico Vittorio Lupo, Carini (IT); Oleg A. Mukhanov, Putnam Valley, NY (US); Marco Arzeo, Pozzuoli (IT)

(21) Appl. No.: 18/822,229

(22) Filed: Sep. 1, 2024

Related U.S. Application Data
(60) Provisional application No. 63/536,367, filed on Sep. 1, 2023.

(51) Int. Cl. G11C 11/44; G11C 29/52; H10N 60/12

(52) U.S. Cl. CPC G11C 11/44; G11C 29/52; H10N 60/12

(57) ABSTRACT

A superconducting integrated circuits (ICs) design based on Josephson junctions, wherein the junctions are biased using a digital phase source (DPS), rather than the standard DC or AC current bias. This DPS enables the use of underdamped junctions, which in turn leads to more compact, lower power, more reliable ICs applied to digital computing, digital signal processing, and readout and control for cryogenic sensor arrays and for quantum computers. This design approach, called Superconducting Sustainable Ballistic Fluxon (SSBF), can be integrated with all logic families based on single-flux-quanta (SFQ), synchronous and asynchronous clocking protocols, and both DC and AC power supplies. SSBF can also be incorporated in automated design tools for scaling superconducting ICs to millions of junctions.

### CROSS REFERENCE TO RELATED APPLICATIONS

The preset application is a Non-provisional of, and claims benefit of priority under 35 U.S.C. § 119(e) from U.S. Provisional Patent Application No. 63/536,367, filed Sep. 1, 2023, the entirety of which is expressly incorporated by reference.

### FIELD OF THE INVENTION

The present invention relates to the field of single flux quantum logic circuits, and more particularly to improved biasing circuitry for single flux quantum logic gates.

### BACKGROUND OF THE INVENTION

A Josephson junction (“JJ”) consists of two layers of a superconductor, with an ultrathin (˜1 nm) layer of an insulator between them, acting as a weak link. The superconducting current between them is given by Iₛ=I_{c} sin φ, where I_{c} is the critical current and φ is the quantum phase difference between the two electrodes. The phase difference is related to the voltage by V=(□/2e) dφ/dt. So the ideal Josephson junction acts like a nonlinear lossless inductance Lⱼ=2e/(□I_{c} cos φ) between the two electrodes. In addition, a junction has a parallel capacitance C and a parallel effective resistance R due to lossy normal electrons, which may also be nonlinear, but approaches Rₙ, the normal-state resistance of the junction.

So, a Josephson junction can be considered a nonlinear parallel LCR resonator. Such a resonator has two characteristic times: RC and L/R. When RC>L/R, the resonator is underdamped, and tends to oscillate at a frequency ω₀=1/√(LC), with a damping time of RC. When L/R<RC, the resonator is overdamped, and tends to decay without oscillation with a damping time L/R. Critical damping corresponds to L/R=RC. In standard terminology, the resonator quality factor is Q=ω₀RC=√(R²C/L). A large Q corresponds to an underdamped oscillator.

A Josephson junction is a bit different, in that it maps onto a pendulum rather than a linear oscillator. The quantum phase φ maps onto the phase angle of the pendulum. If you give a pendulum a kick, it may rotate once if it is damped. But if it is underdamped, it may rotate many times. Single-flux-quantum (SFQ) logic corresponds to a single rotation of the pendulum, which depends on the damping. All classic SFQ logic requires critically damped or overdamped junctions. The relevant parameter in junction technology is β_{c}=Q²=2eR²CI_{c}/□. Large β_{c} corresponds to an underdamped junction.

In practice, most standard Josephson junction technologies yield underdamped junctions with β_{c}˜10 or more. This can be converted to a critically damped junction by adding an external parallel resistance R so that β_{c}˜1 using the parallel combination of the internal resistance and the external resistance. This works, but the resulting shunted junction takes up considerable area.

All existing and recently proposed SuperConducting electronic (“SCE”) circuit technologies (RSFQ [1,2], ERSFQ [3], eSFQ [4], DSFQ [5], HFQ [6], RQL [7], AQFP [8], PCL [9]) are based on analog DC or AC bias supply which is delivered from a common source to the large sections or the entire circuit via the injection taps. In order to deliver the specific designed bias values, different methods are used: resistive dividers (RSFQ, HFQ), current-limiting junctions (ERSFQ, eSFQ, DSFQ), transformers (AQFP, RQL), and even proposed tunable capacitors (PCL) [10].

The analog nature of the above schemes makes the circuit technologies that embody them highly susceptible to fabrication spread and inconsistent operation that raise reliability concerns and hurt prospects for scalability. Moreover, the supply of DC power necessitates current recycling [11] to prevent the excessive growth of the total current, albeit with supplementary resources such as inter-island drivers/receivers that diminish the integration density. AC-based approaches do not have the same electrical limitations as their DC counterparts; however, the multi-phase power distribution leads to area inefficiencies due to the resonators and transformers. Additionally, the challenging task of upholding multi-phase alignment across extensive sections of the circuits results in compromised reliability, significant reduction of operational speeds excessive complexity of multi-phase bias distribution especially for the resonant clocking, significant area overhead and power losses of resonators. Lastly, the complex stack-ups proposed by some solutions, such as those with ferromagnetic and ferroelectric layers, are tailored to specific circuit implementations, impose additional challenges on fabrication processes, and lack versatility for broader logic and architecture implementations.

The possibility of feeding a SFQ circuit from another SFQ circuit was first described in [13]. However, the feeding SFQ circuit was not practical and suffered from low parameter margins. As a result, the modern SCE implementations have low useful circuit density, low reliability, and poor scaling properties. Moreover, the practical circuit realization ended up with higher power dissipation than originally anticipated. In particular, additional power is dissipated in ancillary components like those feeding JTLs and current-limiting JJs of ERSFQ resonator losses in RQL/PCL circuits.

The solutions are typically sought in brute-force approaches requiring ever-more complicated fabrication processes with more and more layers, inserting ferromagnetic and even ferroelectric materials, etc., to the point that some newly proposed logic cells cannot be implemented efficiently with any of existing processes. This makes prospects of drastic improvement in SCE ever more distant in time.

In search for the lowest power logic, ballistic circuits were long viewed as the next step in energy efficient data processing ultimately leading to reversible computation [14,15]. In ballistic circuits, data encoded by fluxons propagate by the input bit inertia through the circuits. However, the energy of the fluxon must be periodically replenished in order to sustain the fluxon propagation and make such computation practical. One method was proposed in [15] using Aharonov-Casher Ring. This solution requires a significant number of junctions and is not practical.

An alternative Josephson junction logic family in the prior art is known as quantum flux parametron or adiabatic quantum flux parametron (QFP or AQFP). See, for example, U.S. Pat. Nos. 4,916,335 and 10,528,886, and article “AQFP: Towards Building Extremely Energy-Efficient Circuits and Systems,” Scientific Reports 9, 10512 (2019). QFP circuits use a specific circuit architecture with complex multi-phase clocks, and can make use of unshunted Josephson junctions to achieve very low power density. However, circuit speed and area density are typically smaller than logic families based on single-flux-quantum (SFQ) logic.

Each reference cited herein is expressly incorporated herein by reference in its entirety, for all purposes. See,
[1]. Mukhanov O A, K. K. Likharev, Semenov V K 1987 Ultimate performance of RSFQ logic circuits IEEE Trans. Magnetics 23 759-762.
[2]. Likharev K K, Semenov V K 1991 RSFQ logic/memory family: a new Josephson-junction technology for sub-terahertz-clock-frequency digital systems IEEE Trans. Appl. Supercond. 1 3-28.
[3]. Kirichenko D E, Sarwana S, Kirichenko A F 2011 Zero static power dissipation biasing of RSFQ circuits IEEE Trans. Appl. Supercond. 21 776-779.
[4]. Mukhanov O A, 2011 Energy-efficient single flux quantum technology, IEEE Trans. Appl. Supercond. 21 760-769.
[5]. Rylov S, 2019 Clockless Dynamic SFQ and Gate with High Input Skew Tolerance,” IEEE Trans. Appl. Supercond. 29 1300805
[6]. Kamiya T et al. 2018 Energy/space-efficient rapid single-flux-quantum circuits by using π-shifted Josephson junctions, IEICE Trans. Electron. E101c 385-390
[7]. Herr Q P, Herr A. Yu, Oberg O T, Ioannidis A. G. 2011 Ultra-low-power superconductor logic Journal of Applied Physics 109 103903.
[8]. Takeuchi N, Ozawa D, Yamanashi Y, Yoshikawa N, 2013 An adiabatic quantum flux parametron as an ultra-low-power logic device, Supercond. Sci. Techn. 26 035010.
[9]. Herr Q, Josephsen T, Herr A 2023 Superconducting Pulse Conservative Logic and Josephson SRAM, Appl. Phys. Lett, 122 182604.
[10]. Herr A et al. 2023 Scaling NbTiN-based ac-powered Josephson digital to 400 M devices/cm2, arXiv: 2303.16792
[11]. Kaplan S 2012 Serial biasing of 16 modular circuits at 50 Gb/s IEEE Trans. Appl. Supercond. 22, 1300103.
[12]. O. A. Mukhanov et al. 1989 RSFQ Logic Arithmetic IEEE Trans. Magn. MAG-25 857-860.
[13]. Semenov V, E. B. Golden and S. K. Tolpygo, 2021 SFQ Bias for SFQ Digital Circuits, IEEE Trans. Appl. Supercond 31 1302207.
[14]. Osborn K, Wustmann W, 2023 Asynchronous Reversible Computing Unveiled Using Ballistic Shift Registers, Phys. Rev. Applied 19 054034
[15]. Wustmann W, Osborn K, 2023 Boosting Fluxons for Improved Digital Logic using an Aharonov-Casher Ring, arXiv: 2305.05021.
[16]. D. Yohannes, M. Renzullo, J. Vivalda, A. C. Jacobs, M. Yu, J. Walter, A. F. Kirichenko, I. V. Vernik, O. A. Mukhanov, 2023 High Density Fabrication Process for Single Flux Quantum Circuits, Appl. Phys. Lett. 122, 212601.
[17]. G. Tzimpragos et al. Proceedings of ISCA, 2021.
[18] Semenov, Vasili K., Evan B. Golden, and Sergey K. Tolpygo. “Sfq bias for sfq digital circuits.” IEEE Transactions on Applied Superconductivity 31, no. 5 (2021): 1-7.
[19] Semenov, Vasili K., and Dmitri V. Averin. “SFQ control circuits for Josephson junction qubits.” IEEE transactions on applied superconductivity 13, no. 2 (2003): 960-965.
[20] Semenov, Vasili K., Yuri A. Polyakov, and Sergey K. Tolpygo. “New AC-powered SFQ digital circuits.” IEEE Transactions on Applied Superconductivity 25, no. 3 (2014): 1-7.
[21] Joukov, Nikolai, Yoshihito Hashimoto, and Vasili Semenov. “Matching Josephson junctions with microstrip lines for SFQ pulses and weak signals.” IEICE transactions on electronics 85, no. 3 (2002): 636-640.
[22] Fourie, Coenrad J. “Extraction of de-biased sfq circuit verilog models.” IEEE Transactions on Applied Superconductivity 28, no. 6 (2018): 1-11.
[23] Kirichenko, Alex F., Saad Sarwana, Darren K. Brock, and Masoud Radpavar. “Pipelined dc-powered SFQ RAM.” IEEE transactions on applied superconductivity 11, no. 1 (2001): 537-540.
[24] Yamanashi, Yuki, Sotaro Nakaishi, Akira Sugiyama, Naoki Takeuchi, and Nobuyuki Yoshikawa. “Design methodology of single-flux-quantum flip-flops composed of both 0- and π-shifted Josephson junctions.” Superconductor Science and Technology 31, no. 10 (2018): 105003.
[25] Kang, J. H., and S. B. Kaplan. “Current recycling and SFQ signal transfer in large scale RSFQ circuits.” IEEE transactions on applied superconductivity 13, no. 2 (2003): 547-550.
[26] Chen, Olivia, Ruizhe Cai, Yanzhi Wang, Fei Ke, Taiki Yamae, Ro Saito, Naoki Takeuchi, and Nobuyuki Yoshikawa. “Adiabatic quantum-flux-parametron: Towards building extremely energy-efficient circuits and systems.” Scientific reports 9, no. 1 (2019): 10514. www.nature.com/articles/s41598-019-46595-w
Takeuchi, Naoki, Dan Ozawa, Yuki Yamanashi, and Nobuyuki Yoshikawa. “An adiabatic quantum flux parametron as an ultra-low-power logic device.” Superconductor Science and Technology 26, no. 3 (2013): 035010.
Takeuchi, Naoki, Taiki Yamae, Christopher L. Ayala, Hideo Suzuki, and Nobuyuki Yoshikawa. “Adiabatic quantum-flux-parametron: A tutorial review.” IEICE Transactions on Electronics 105, no. 6 (2022): 251-263.
Arai, Kota, Naoki Takeuchi, Taro Yamashita, and Nobuyuki Yoshikawa. “Adiabatic quantum-flux-parametron with π Josephson junctions.” Journal of Applied Physics 125, no. 9 (2019).
China, F., T. Narama, N. Takeuchi, T. Ortlepp, Y. Yamanashi, and N. Yoshikawa. “Design and demonstration of interface circuits between rapid single-flux-quantum and adiabatic quantum-flux-parametron circuits.” IEEE Transactions on Applied Superconductivity 26, no. 5 (2016): 1-5.
Yamazaki, Yuichi, Naoki Takeuchi, and Nobuyuki Yoshikawa. “A compact interface between adiabatic quantum-flux-parametron and rapid single-flux-quantum circuits.” IEEE Transactions on Applied Superconductivity 31, no. 5 (2021): 1-5.
Takeuchi, N., K. Ehara, K. Inoue, Y. Yamanashi, and N. Yoshikawa. “Margin and energy dissipation of adiabatic quantum-flux-parametron logic at finite temperature.” IEEE transactions on applied superconductivity 23, no. 3 (2012): 1700304-1700304.
Narendran, S. “Design of Hybrid Counter using Adiabatic Quantum Flux Parametron.” In Journal of Physics: Conference Series, vol. 2267, no. 1, p. 012147. IOP Publishing, 2022.
Takeuchi, Naoki, Thomas Ortlepp, Yuki Yamanashi, and Nobuyuki Yoshikawa. “Novel latch for adiabatic quantum-flux-parametron logic.” Journal of Applied Physics 115, no. 10 (2014).
Inoue, Kenta, Naoki Takeuchi, Kohei Ehara, Yuki Yamanashi, and Nobuyuki Yoshikawa. “Simulation and experimental demonstration of logic circuits using an ultra-low-power adiabatic quantum-flux-parametron.” IEEE transactions on applied superconductivity 23, no. 3 (2012): 1301105-1301105.
Blackburn, L. Camron, Evan Golden, Alex Wynn, Andrew Wagner, and Neil Gershenfeld. “Design and simulation of phase synchronizer for adiabatic quantum flux parametron circuits.” IEEE Transactions on Applied Superconductivity 33, no. 5 (2023): 1-5.
Takeuchi, Naoki, Yuki Yamanashi, and Nobuyuki Yoshikawa. “Measurement of 10 zJ energy dissipation of adiabatic quantum-flux-parametron logic using a superconducting resonator.” Applied Physics Letters 102, no. 5 (2013).
Yamae, Taiki, Naoki Takeuchi, and Nobuyuki Yoshikawa. “Systematic method to evaluate energy dissipation in adiabatic quantum-flux-parametron logic.” Journal of Applied Physics 126, no. 17 (2019).
Narendran, S. “Design of decade counter using Adiabatic Quantum Flux Parametron.” In AIP Conference Proceedings, vol. 2516, no. 1. AIP Publishing, 2022.
Fang, Kun, Naoki Takeuchi, Takumi Ando, Yuki Yamanashi, and Nobuyuki Yoshikawa. “Multi-excitation adiabatic quantum-flux-parametron.” Journal of Applied Physics 121, no. 14 (2017).
China, F., T. Narama, N. Takeuchi, T. Ortlepp, Y. Yamanashi, and N. Yoshikawa. “Study of Signal Interface between Single Flux Quantum Circuit and Adiabatic Quantum Flux Parametron.” In 2015 15th International Superconductive Electronics Conference (ISEC), pp. 1-3. IEEE, 2015.
Takeuchi, Naoki, Yuki Yamanashi, and Nobuyuki Yoshikawa. “Adiabatic quantum-flux-parametron cell library adopting minimalist design.” Journal of Applied Physics 117, no. 17 (2015).
Xu, Qiuyun, Christopher L. Ayala, Naoki Takeuchi, Yuki Yamanashi, and Nobuyuki Yoshikawa. “HDL-based modeling approach for digital simulation of adiabatic quantum flux parametron logic.” IEEE Transactions on Applied Superconductivity 26, no. 8 (2016): 1-5.
Chen, Olivia, Ruizhe Cai, Yanzhi Wang, Fei Ke, Taiki Yamae, Ro Saito, Naoki Takeuchi, and Nobuyuki Yoshikawa. “Adiabatic quantum-flux-parametron: Towards building extremely energy-efficient circuits and systems.” Scientific reports 9, no. 1 (2019): 10514.
Takeuchi, Naoki, Shuichi Nagasawa, Fumihiro China, Takumi Ando, Mutsuo Hidaka, Yuki Yamanashi, and Nobuyuki Yoshikawa. “Adiabatic quantum-flux-parametron cell library designed using a 10 kA cm⁻² niobium fabrication process.” Superconductor Science and Technology 30, no. 3 (2017): 035002.
Marakkalage, Dewmini Sudara, Heinz Riener, and Giovanni De Micheli. “Optimizing adiabatic quantum-flux-parametron (AQFP) circuits using an exact database.” In 2021 IEEE/ACM International Symposium on Nanoscale Architectures (NANOARCH), pp. 1-6. IEEE, 2021.
Narama, Tatsuya, Yuki Yamanashi, Naoki Takeuchi, Thomas Ortlepp, and Nobuyuki Yoshikawa. “Demonstration of 10 k gate-scale adiabatic-quantum-flux-parametron circuits.” In 2015 15th International Superconductive Electronics Conference (ISEC), pp. 1-3. IEEE, 2015.
Yamae, Taiki, Naoki Takeuchi, and Nobuyuki Yoshikawa. “Binary counters using adiabatic quantum-flux-parametron logic.” IEEE Transactions on Applied Superconductivity 31, no. 2 (2020): 1-5.
Takeuchi, Naoki, Yuki Yamanashi, and Nobuyuki Yoshikawa. “Recent progress on reversible quantum-flux-parametron for superconductor reversible computing.” IEICE Transactions on Electronics 101, no. 5 (2018): 352-358.
Ayala, Christopher L., Olivia Chen, and Nobuyuki Yoshikawa. “AQFPTX: Adiabatic quantum-flux-parametron timing extraction tool.” In 2019 IEEE International Superconductive Electronics Conference (ISEC), pp. 1-3. IEEE, 2019.
Takeuchi, N., Y. Yamanashi, and N. Yoshikawa. “Simulation of sub-kBT bit-energy operation of adiabatic quantum-flux-parametron logic with low bit-error-rate.” Applied Physics Letters 103, no. 6 (2013).
Takeuchi, Naoki, Hideo Suzuki, Conrad J. Fourie, and Nobuyuki Yoshikawa. “Impedance design of excitation lines in adiabatic quantum-flux-parametron logic using InductEx.” IEEE Transactions on Applied Superconductivity 31, no. 5 (2021): 1-5.
Ayala, Christopher L., Ro Saito, Tomoyuki Tanaka, Olivia Chen, Naoki Takeuchi, Yuxing He, and Nobuyuki Yoshikawa. “A semi-custom design methodology and environment for implementing superconductor adiabatic quantum-flux-parametron microprocessors.” Superconductor Science and Technology 33, no. 5 (2020): 054006.
Ando, Takumi, Shuichi Nagasawa, Naoki Takeuchi, Naoki Tsuji, Fumihiro China, Mutsuo Hidaka, Yuki Yamanashi, and Nobuyuki Yoshikawa. “Three-dimensional adiabatic quantum-flux-parametron fabricated using a double-active-layered niobium process.” Superconductor Science and Technology 30, no. 7 (2017): 075003.
Okuma, Yukihiro, Naoki Takeuchi, Yuki Yamanashi, and Nobuyuki Yoshikawa. “Miniaturization of adiabatic quantum-flux-parametron circuits by adopting offset buffers.” Superconductor Science and Technology 32, no. 6 (2019): 065007.
Cai, Ruizhe, Ao Ren, Olivia Chen, Ning Liu, Caiwen Ding, Xuchai Qian, Jie Han, Wenhui Luo, Nobuyuki Yoshikawa, and Yanzhi Wang. “A stochastic-computing based deep learning framework using adiabatic quantum-flux-parametron superconducting technology.” In Proceedings of the 46th International Symposium on Computer Architecture, pp. 567-578. 2019.
Saito, Ro, Christopher L. Ayala, Olivia Chen, Tomoyuki Tanaka, Tomohiro Tamura, and Nobuyuki Yoshikawa. “Logic synthesis of sequential logic circuits for adiabatic quantum-flux-parametron logic.” IEEE Transactions on Applied Superconductivity 31, no. 5 (2021): 1-5.
US Patent and Pub. App. Nos. 20220399145; 11508896; 20220237495; 11406583; 9853645; 11385099; 10680617; 20230187801; 20230208400; 20230210022; 20220149841; U.S. Pat. Nos. 11,342,919; 11,289,156; 10,778,229; 5,140,324; 5,170,080; 5,191,236; 5,198,815; 5,233,242; 5,233,243; 5,327,130; 5,341,136; 5,358,928; 5,436,451; 5,629,889; 5,910,414; 5,912,503; 5,942,997; 5,963,351; 6,051,440; 6,078,517; 6,157,329; 6,188,236; 6,242,939; 6,331,805; 6,483,339; 6,486,694; 6,486,756; 6,518,673; 6,549,059; 6,580,310; 6,661,560; 6,724,216; 6,734,454; 6,756,925; 6,771,201; 6,777,808; 6,922,066; 7,002,366; 7,075,171; 7,129,870; 7,268,713; 7,300,909; 7,323,869; 7,365,663; 7,449,769; 7,501,877; 7,505,310; 7,554,369; 7,724,083; 7,772,871; 7,782,077; 7,843,209; 7,852,106; 7,868,645; 7,876,869; 7,911,265; 7,944,253; 8,018,244; 8,032,196; 8,045,660; 8,130,880; 8,169,231; 8,179,133; 8,508,280; 8,514,986; 8,571,614; 8,861,619; 8,927,487; 8,933,695; 9,020,079; 9,240,773; 9,252,825; 9,325,173; 9,438,246; 9,443,576; 9,473,124; 9,509,315; 9,520,180; 9,552,862; 9,577,690; 9,588,191; 9,647,662; 9,710,586; 9,722,589; 9,741,918; 9,747,968; 9,767,238; 9,780,765; 9,787,312; 9,812,836; 9,818,064; 9,853,645; 9,876,505; 9,887,000; 9,906,248; 9,928,948; 9,929,978; 9,991,864; 9,998,122; 10,090,841; 10,121,754; 10,122,351; 10,122,352; 10,134,972; 10,164,606; 10,171,086; 10,210,460; 10,224,475; 10,236,869; 10,242,968; 10,256,635; 10,283,694; 10,333,047; 10,333,049; 10,339,239; 10,355,677; 10,355,696; 10,366,340; 10,381,541; 10,396,269; 10,424,935; 10,460,796; 10,491,178; 10,505,095; 10,516,089; 10,528,886; 10,546,993; 10,55,2756; 10,572,816; 10,586,909; 10,58,7245; 10,622,977; 10,637,479; 10,658,987; 10,680,617; 10,725,361; 10,734,568; 10,748,079; 10,749,095; 10,797,684; 10,824,048; 10,852,366; 10,886,049; 10,903,809; 10,917,096; 10,950,299; 10,989,767; 10,998,869; 11,005,024; 11,024,790; 11,054,598; 11,063,201; 11,108,380; 11,115,027; 11,127,893; 11,200,947; 11,201,608; 11,211,799; 11,271,405; 11,283,445; 11,289,156; 11,289,639; 11,300,853; 11,342,919; 11,346,872; 11,362,656; 11,385,099; 11,406,583; 11,411,564; 11,418,175; 11,431,322; 11,476,842; 11,482,656; 11,508,896; 11,522,115; 11,536,780; 11,557,708; 11,652,480; 11,687,819; 11,717,475; 11,722,135; 11,730,066; 11,742,326; 20010025012; 20020169079; 20020190381; 20030028338; 20030039138; 20030058026; 20030183935; 20040134967; 20040223380; 20040243377; 20040266627; 20050029512; 20050040843; 20050062131; 20050078022; 20050215436; 20060049891; 20060255987; 20070049097; 20070069339; 20070075752; 20080048902; 20080051292; 20080129368; 20080186064; 20080297230; 20090078931; 20090267635; 20090319757; 20100033206; 20100033252; 20100207657; 20100237899; 20110031994; 20110288823; 20120012818; 20120205981; 20130015885; 20130043945; 20130258595; 20130296227; 20140113828; 20140286465; 20150119253; 20150178432; 20150229343; 20150263736; 20160028402; 20160028403; 20160035404; 20160164505; 20160197482; 20160197628; 20170017742; 20170062107; 20170069367; 20170104695; 20170133336; 20170133577; 20170163301; 20170201224; 20170250540; 20170329883; 20170345990; 20170359072; 20170373044; 20180005887; 20180012932; 20180013052; 20180101785; 20180101786; 20180102166; 20180102469; 20180102470; 20180145664; 20180294815; 20190036515; 20190188596; 20190190463; 20190207076; 20190229690; 20190245353; 20190245544; 20190288178; 20190326501; 20200027502; 20200036192; 20200111016; 20200136008; 20200136626; 20200287550; 20200297286; 20200333263; 20200350880; 20200373475; 20210013391; 20210036206; 20210119102; 20210135084; 20210226635; 20210265964; 20210336610; 20210399199; 20220000373; 20220012623; 20220036943; 20220052662; 20220065954; 20220093841; 20220149841; 20220166222; 20220166223; 20220190830; 20220208726; 20220236623; 20220237495; 20220286129; 20220286136; 20220286137; 20220311400; 20220328747; 20220393089; 20220399145; 20230006626; 20230010205; 20230019017; 20230022450; 20230043001; 20230052753; 20230068621; 20230128586; 20230143506; 20230145418; 20230180630; and 20230210022.

### SUMMARY OF THE INVENTION

One aspect of the invention is to enable use of underdamped or unshunted or undershunted JJs in single flux quantum (“SFQ”) logic and its variants. These underdamped or unshunted or undershunted JJs consume less area than fully damped or critically damped JJs, allowing higher density integrated circuits. This requires rethinking how energy for operation of the Josephson junctions is provided.

The present invention uses circuit designs from traditional SFQ logic families, but provides a DC or single-phase AC biasing scheme to enable the use of compact unshunted junctions, as well as a superior combination of energy efficiency, area density, and circuit speed.

An analog bias circuit dissipates energy, due to resistive (or corresponding) losses, which are continuous, and significantly more than the energy in the pulses produced by the circuit (analogous to the work performed by the circuit). One solution to this problem is to provide the JJ logic with an optimal amount of energy, and replenish that energy as the JJ logic operates, instead of employing a continuous dissipative bias current.

The JJ charging circuit may itself consume energy, but that is mitigated in three different ways. First, using ballistic logic principles, the charging circuitry may be selectively provided to a subset of the JJ logic gates, e.g., 50%, with the remainder unbiased and operating in a ballistic mode. Second, assuming a statistical distribution of data logic states, if the charging circuitry has an energy consumption dependent on pulses and not absence of pulses, the consumption may also be statistically reduced, e.g., by 50%. Third, undamped gates or ballistic logic consumes less energy than critically damped gates.

In the case of digital phase source biasing, the charging circuit may itself be used as a logical process, potentially providing greater logic efficiency given an effectively higher complexity structure. For example, the state of the digital bias may be used as a memory of register, an accumulator or integrator, or provide other functions. Additional control logic may be provided to fully exploit these capabilities.

The preferred implementation of the technology provides a digital phase source (DPS) which stores quantized fluxon(s). The storage is not limited to binary storage, and therefore multiple quanta of flux may be stored. The DPS is configured to deliver a single quantized pulse of flux (2π) to the gate as a charging energy. This pulse corresponds to the pulse produced by the logic gate, yielding high efficiency, especially where the DPS is itself charged only as necessary to replenish its transferred energy. The DPS delivers the pulse charge to the logic when there is a phase difference, However, when the DPS and logic have the same phase, no energy is transferred.

The interconnect between gates can be formed using passive transmission lines (PTLs), unbiased Josephson Transmission Lines (JTLs) made of unshunted JJs, or long JJ (LJJs).

The DPS receives energy from a clock, which may be an AC or DC clock. An AC clock is inductively coupled and does not require a respective bias current. A DC clock would typically require a current source bias, but as noted above, the number of current bias sources would be lower than if all logic gates had their own current bias source.

Therefore, the present technology exploits an architecture where Josephson junctions are biased so that only a single 360° (2π) phase rotation is possible in any transition, that would stabilize SFQ logic even for underdamped junctions.

A new superconducting highly energy-efficient circuit technology is therefore provided which addresses many problems of the existing and recently proposed superconducting digital logic families. This is called Superconducting Sustainable Ballistic Fluxon™ (SSBF) technology. A key enabling feature of this new circuit technology is the discretization of the power distribution to data processing cells. This is achieved by a new digital phase source (DPS) which offers quantized energy replenishment, compensating for losses exclusively where and when needed.

The data processing circuits are bias free and can process data ballistically. Data is represented by fluxons or single flux quanta. The inevitable loss of fluxon energy during processing is replenished by DPS which provides the quantized amounts of energy, so the fluxon can propagate further in the circuit. The SSBF can be used with different logic architectures supporting synchronous or asynchronous data processing.

In SSBF, superconducting circuits are divided into two parts: passive (bias-free) data processing circuits (“DPC”), and active digital phase source (DPS) circuits. The DPC are bias-free, therefore they can be constructed with unshunted Josephson junctions (JJs). The DPC can process data ballistically. This enables high density layouts compared to the traditional SFQ circuits due to the lack of JJ shunts.

The DPS provides quantized energy replenishment to the DPC only when needed (on-demand), i.e., if there is no data fluxon passing through the circuits, no replenishment energy is supplied, and no power is dissipated. The DPS provides biasing (energy-replenishment) only where it is needed. It is not necessary to attach DPS to every gate. The number of DPS can be less than the number of ballistic logic gates.

The DPS itself can be fed with AC or DC bias.

Asynchronous or synchronous DPC logic architectures can be supported, and as noted, the DPS may be configured to provide additional functionality beyond supplying operating energy for the DPC. On the other hand, the DPS may be regularized to supply only the required energy replenishment, and otherwise not alter the DPC functions.

Parameter margins of SSBF are higher, since circuits are bias-free, JJs are unbiased and refractory to noise and interference. Parameter margins are not affected by scaling, since DPS provides phase bias not shared with other cells.

This approach fundamentally addresses limitations in both the density and reliability of Super Conducting Electronics (SCE). Specifically, circuit density of SCE is presently limited by the geometric inductance required to store flux quanta, shunt resistors for Josephson junctions, and wide low-impedance transmission lines. In addition, the present approach drastically reduces ancillary component counts used for clock and bias distribution, long Josephson transmission lines (“JTLs”) for interconnect, and buffer cells. Overall circuit density may be increased by over an order of magnitude.

Reliability is also improved. The existing SCE circuits are plagued by the low AC or DC bias margins quickly falling with circuit scaling and higher operation speed. Sensitivity to ground return currents, interference from neighboring cells, non-locality of bias current affecting other cells, sensitivity to flux trapping and other factors are affecting the circuit reliability and scaling. These problems stem from the currently used analog AC or DC current biasing schemes preventing reliable parameter optimization with circuit scaling.

Finally, the practical implementations of SCE circuits end up with compromises in the energy-efficiency, low latency and clock speed characteristics.

It is therefore an object to provide a superconducting digital phase source for a superconducting digital circuit, comprising: a power input port configured to receive power from a power source; a storage circuit configured to store a fluxon or single flux quantum (SFQ) based on energy from the power input port; and a digital power output port configured to generate a phase output at a specified phase value from the stored fluxon or single flux quantum (SFQ).

The storage circuit may comprise a plurality of Josephson junctions, wherein at least one of the Josephson junctions is critically damped, underdamped, or completely undamped.

It is also an object to provide a superconducting digital phase source for a superconducting digital circuit, comprising: a storage circuit configured to store a fluxon or single flux quantum (SFQ) based on energy from a power source; and a digital power output port configured to generate a phase output at a specified phase value from the stored fluxon or single flux quantum (SFQ).

It is a further object to provide a method of operating a superconducting digital circuit, comprising: providing a storage circuit configured to store a fluxon or single flux quantum (SFQ); and a digital power output port configured to generate a phase output at a specified phase value from the stored fluxon or single flux quantum (SFQ); receiving logic pulses into the storage circuit; storing power from the logic pulses in the storage circuit as the fluxon or single flux quantum (SFQ); and generating the phase output at a specified phase value from the stored fluxon or single flux quantum (SFQ).

More generally, the technology provides a system and method that receives information pulses, e.g., fluxons, which comprise energy, storing at least a portion of the energy representing the information, and an output which is powered by the stored energy representing the information or a logical transformation of the information at a later point in time.

The storage circuit may comprise a plurality of Josephson junctions, an at least one of the Josephson junctions may be underdamped.

The power source may comprise a clock input and the storage circuit comprises D-flip-flop.

The digital power output port may supply the phase output at the specified phase value to a data processing circuit comprising a plurality of Josephson junctions, and at least one of the junctions may be undamped or underdamped. The data processing circuit may comprise an asynchronous xSFQ logic circuit or DSFQ logic circuit. The data processing circuit may comprise a synchronous the RSFQ, ERSFQ, ESFQ, HFQ, RQL, or PCL logic circuit.

The superconducting digital phase source may further comprise a passive data processing circuit, wherein the digital power output port is configured to supply the phase output at the specified phase value to the passive data processing circuit as a sole energy source to support information propagation. The phase output may supply energy to the passive data processing circuit to replenish energy transmitted to support information propagation.

The superconducting digital phase may further comprise a data processing circuit configured to store a fluxon or single flux quantum (SFQ) at a first phase, and to communicate the fluxon or single flux quantum (SFQ) as information to thereby enter a second phase, wherein the phase output at the specified phase value is configured to generate the phase output to selectively supply the fluxon or single flux quantum (SFQ) to the data processing circuit in the second phase to return the data processing circuit to the first phase, and to generate no fluxon or single flux quantum (SFQ) when the data processing circuit is in the first phase.

The storage circuit may have a phase, and be configured to transfer the fluxon or single flux quantum (SFQ) to the digital power output port as the phase output when a phase difference is present at the digital power output port, else continue to store the fluxon or single flux quantum (SFQ).

The storage circuit may have a capacity to store a single fluxon or single flux quantum (SFQ), and the generated phase output at the specified phase value may be dependent on a first phase based on the fluxon or single flux quantum (SFQ) stored in the storage circuit and a second phase dependent on a state of a circuit present at the digital power output port.

The storage circuit may have a capacity to store a plurality of fluxons or single flux quanta (SFQ), and the generated phase output at the specified phase value may be dependent on a first phase based on a number of the fluxon or single flux quantum (SFQ) stored in the storage circuit and a second phase dependent on a multilevel quantized state of a circuit present at the digital power output port.

The power source may receive sufficient power only to replenish power transferred through the digital power output port as the generated phase output.

The superconducting digital phase source may further comprise: a first data processing circuit configured to receive the phase output and a first fluxon or single flux quantum (SFQ) information signal as sole sources of power for a second fluxon or single flux quantum (SFQ) information signal produced by the first data processing circuit; and a second data processing circuit configured to receive the second fluxon or single flux quantum (SFQ) information signal as a sole source of power for a third fluxon or single flux quantum (SFQ) information signal produced by the second data processing circuit.

The storage circuit may comprise a plurality of storage circuits, each being configured to store a respective fluxon or single flux quantum (SFQ) pulse, and wherein digital power output port comprises a plurality of digital phase sources, the superconducting digital phase source further comprising a plurality of data processing circuits, configured to receive a respective phase output from a respective digital power output port, wherein the plurality of data processing circuits are configured for serial processing of digital data.

A first serially connected data processing circuit may receive at least a portion of its operating power from a respective digital phase source, and a second serially connected data processing circuit receives all of its operating power from the first serially connected data processing circuit.

The plurality of data processing circuits may each comprise an unshunted, underdamped Josephson junction which produces an oscillating output, and the plurality of data processing circuits produce respective outputs with only insignificant ringing.

It is a further object to provide a superconducting integrated circuit, comprising: a plurality of passive logic circuits configured for serial processing of digital data, each comprising a plurality of first Josephson junctions, at least one of the plurality of first Josephson junctions being underdamped; and a plurality of active digital phase sources each comprising a plurality of second Josephson junctions, at least one of the plurality of second Josephson junctions being underdamped, wherein each active digital phase source provides power for a respective passive logic circuit.

The underdamped first Josephson junctions may be fabricated without a shunt resistor and the underdamped second Josephson junctions are fabricated without a shunt resistor.

The plurality of passive logic circuits are configured to at least one of: perform quantum error correction; control a quantum computing system; read out information from a quantum computing system, and support operation of a quantum computing system comprising a superconducting qubit, selected from the group consisting of a transmon, a flux qubit, a charge qubit, a phase qubit, and a fluxonium.

The plurality of passive logic circuits may be configured to provide control and readout for an array of superconducting sensors, comprising at least one of SQUIDs, transition edge sensors, superconducting nanowires, kinetic inductance detectors, and superconducting tunnel junction detectors.

The superconducting integrated circuit may further comprise a plurality of second passive logic circuits configured for serial processing of digital data, each comprising a plurality of third Josephson junctions, at least one of the plurality of third Josephson junctions being underdamped, wherein each second passive logic circuit receives sole operating power from an information signal produced by a respective passive logic circuit.

The power input port may be configured to accept AC power or DC Power.

The AC input may be a clock input.

The DC power may be provided by a clock signal.

The storage circuit may comprise a D-flip-flop.

The digital power output port may be configured to supply the phase output at the specified phase value to a data processing circuit.

The data processing circuit may comprise a plurality of Josephson junctions, and wherein at least one of the junctions is undamped or underdamped.

The data processing circuit may comprise a T-flip-flop.

The data processing circuit may comprise a single-flux-quantum (SFQ) logic circuit.

The SFQ logic circuit may comprise an asynchronous logic circuit.

The asynchronous logic circuit may comprise at least one circuit of the xSFQ logic family or the DSFQ logic family.

The SFQ logic circuit may comprise a synchronous logic circuit.

The synchronous logic circuit may comprise at least one circuit of at least one of the RSFQ, ERSFQ, eSFQ, HFQ, RQL, and PCL logic families.

The superconducting digital phase source may further comprise a passive data processing circuit, wherein the digital power output port is configured to supply the phase output at the specified phase value to the passive data processing circuit as a sole energy source to support information propagation.

The phase output may supply energy to the passive data processing circuit to replenish energy transmitted to support information propagation.

The storage circuit may have a capacity to store a single fluxon or single flux quantum (SFQ).

The generated phase output at the specified phase value may be dependent on a first phase based on the fluxon or single flux quantum (SFQ) stored in the storage circuit and a second phase dependent on a state of a circuit present at the digital power output port.

The storage circuit may have a capacity to store a plurality of fluxons or single flux quanta (SFQ).

The generated phase output at the specified phase value may be dependent on a first phase based on a number of the fluxon or single flux quantum (SFQ) stored in the storage circuit and a second phase dependent on a multilevel quantized state of a circuit present at the digital power output port.

The power input port may be further configured to receive power from the power source only to replenish power transferred through the digital power output port as the generated phase output.

It is another object to provide a superconducting digital logic circuit, comprising: a plurality of digital phase sources, each comprising a power input port configured to receive power from a power source, a storage circuit configured to store a fluxon or single flux quantum (SFQ) based on energy from the power input port, and a digital power output port configured to generate a phase output at a specified phase value from the stored fluxon or single flux quantum (SFQ); and a plurality of data processing circuits, configured to receive a respective phase output from a respective digital phase source, wherein the plurality of data processing circuits are configured for serial processing of digital data.

A single digital phase source may supply operating power for a plurality of data processing circuits.

A first serially connected data processing circuit may receive at least a portion of its operating power from a respective digital phase source, and a second serially connected data processing circuit receives all of its operating power from the first serially connected data processing circuit.

The plurality of data processing circuits may each comprise an unshunted Josephson junction.

The plurality of data processing circuits may produce an output with only insignificant ringing, e.g., from an undamped or underdamped output. As used herein, “insignificant ringing” means that, at the data rate, any ringing does not increase the error rate beyond a specification, or produce intersymbol interference. In the circuit design process, ringing may be modelled, and shunts strategically added as required to meet required specifications. Note that the adaptive addition of shunts may result in a variety of standard cells for respective functions, interfering with regular layouts. In general, if the modelled ringing increases the error rate less than 100% of a critically damped junction at the data rate (i.e., less than double the error rate), then the ringing is insignificant. Where the error rate causes the error rate to exceed a specification threshold, a data rate may be limited, error correction logic implemented, or partial or full shunting (or other damping) added to the junctions.

The plurality of data processing circuits may each comprise an underdamped Josephson junction and produce an oscillating output.

It is a further object to provide a superconducting integrated circuit, comprising: a plurality of passive logic circuits configured for serial processing of digital data, each comprising a plurality of first Josephson junctions, at least one of the plurality of first Josephson junctions being underdamped; and a plurality of active digital phase sources each comprising a plurality of second Josephson junctions, at least one of the plurality of second Josephson junctions being underdamped, wherein each active digital phase source provides power for a respective passive logic circuit.

The underdamped first Josephson junctions may be fabricated without a shunt resistor.

The underdamped second Josephson junctions may be fabricated without a shunt resistor.

The plurality of passive logic circuits may be configured to perform classical digital computing operations.

The plurality of passive logic circuits may be configured to perform quantum error correction.

The plurality of passive logic circuits may be configured to control a quantum computing system.

The plurality of passive logic circuits may be configured to read out information from a quantum computing system.

The plurality of passive logic circuits may support operation of a quantum computing system comprising a superconducting qubit, selected from the group consisting of a transmon, a flux qubit, a charge qubit, a phase qubit, and a fluxonium.

The plurality of passive logic circuits may be configured to provide control and readout for an array of cryogenic sensors. The cryogenic sensors may comprise superconducting sensors, comprising at least one of SQUIDs, transition edge sensors, superconducting nanowires, kinetic inductance detectors, and superconducting tunnel junction detectors.

The plurality of first Josephson junctions or second Josephson junctions may comprise one of Nb, Al, Ta, TaN, NbN, NbTi, NbTiN, MoGe, MgB₂, YBa₂Cu₃O₈.

The superconducting integrated circuit may be configured to operate at 40K, 30K, 20K, 10K, 4K, 1K, 0.1K, and/or 0.01K.

The superconducting integrated circuit may comprise at least 1,000, 10,000, 100,000, or 1,000,000 Josephson junctions.

The superconducting integrated circuit may further comprise a plurality of second passive logic circuits configured for serial processing of digital data, each comprising a plurality of third Josephson junctions, at least one of the plurality of third Josephson junctions being underdamped, wherein each second passive logic circuit receives sole operating power from an information signal produced by a respective passive logic circuit.

The superconducting integrated circuit may have a density of Josephson junctions greater than 1 million junctions per square centimeter.

The plurality of passive logic circuits may be configured to operate at a frequency greater than 10 GHz.

The superconducting integrated circuit may have a power dissipation per Josephson junction is less than 10 nW.

The superconducting integrated circuit may be configured to operate on a cryocooler.

The superconducting integrated circuit may be configured to operate on a dilution refrigerator.

It is a still further object to provide a method of designing a superconducting integrated circuit, comprising: providing a logical description of the superconducting integrated circuit; using a design automation tool to define a set of interconnected logic elements which meet the logical description, the logic elements comprising underdamped Josephson junctions; determining power and timing constraints of the set of interconnected logic elements; and defining a respective active digital phase source to provide power for a first subset of the logic elements, wherein a second subset of the logic elements receive operating power only from an information signal from a preceding logic element in a sequential data processing sequence.

The method may further comprise defining a layout of the superconducting integrated circuit.

A further object provides a superconducting logical system, comprising: a storage circuit configured to store a logical fluxon or single flux quantum (SFQ) pulse in a loop, comprising information received at a time, and a digital output port configured to generate an output dependent on the information, after the time, using power stored in the loop.

A still further object provides a superconducting logical method, comprising: storing a logical fluxon or single flux quantum (SFQ) pulse in a loop, comprising information received at a time, and generating an output dependent on the information, after the time, using power stored in the loop.

Another object comprises a superconducting integrated circuit, comprising: an input port, configured to receive a first information pulse; a plurality of Josephson junctions, configured as a logical circuit having at least one fluxon storage element comprising a loop configured to store energy from the first information pulse; a bias circuit, configured to bias the plurality of Josephson junctions using a digital phase source comprising underdamped or undamped Josephson junctions; and an output port, configured to generate a second information pulse dependent on the logic circuits, and the first information pulse.

### BRIEF DESCRIPTION OF THE DRAWINGS

FIG. 1 shows a block diagram of an SSBF circuit showing the injection of energy from DPS between ballistic bias-free logic gates. The DPS cells are inserted only where needed.

FIG. 2A shows an example of an optimized SSBF TFF with the DPS to replenish the energy of the output fluxon, the optimized circuit schematics with margins exceeding +30-40% for all parameters. Circles indicate unshunted JJs.

FIG. 2B shows the example of the optimized SSBF TFF with the DPS to replenish the energy of the output fluxon of FIG. 2A, a micrograph of the fabricated SSBF circuit using SEEQC's SFQ-C5SL process. The lack of shunt resistors enables a substantial decrease in circuit area.

FIG. 3 shows a block diagram of the digital phase source technology with a DC biased digital phase source (DPS), which provides quantized energy replenishment of the data processing circuit (DPU).

FIG. 4 shows a DC biased digital phase source (DPS), which receives a clock, which is passed to a subsequent circuit, and a DC bias, and produces an on-demand quantized replenishment for a passive data processing unit (DPU) dependent on a status of the DPU.

FIG. 5 shows a series of DC biased digital phase sources (DPS) which propagate a clock signal in a chain, with the clock as the DC bias source, and each DPS providing power for a data processing unit (DPU) in a serial data processing chain.

FIG. 6 shows an AC biased digital phase source (DPS), which receives an AC bias oscillating signal and produces an on-demand quantized replenishment for a passive data processing unit (DPU) dependent on a status of the DPU.

FIG. 7 shows a series of AC biased digital phase sources (DPS), and each DPS providing power for a ballistic logic cell in a serial data processing chain.

FIG. 8 shows a typical circuit for a digital phase source (DPS) connected to a data AC biased processing unit (DPU), in which the AC signal provides replenishment for a single flux quantum from the DPS portion of the circuit (upper right), to a DPU portion of the circuit (lower left). Conventional shunted junctions are used.

FIG. 9 shows traces of simulated signals of the circuit according to FIG. 8.

FIG. 10 shows an embodiment of the circuit according to FIG. 3, in which circled Josephson junctions are unshunted.

FIG. 11 shows graphs of various signals within the circuit according to the embodiment of FIG. 10, and which shows ringing with respect to comparable FIG. 9.

FIG. 12 shows a block diagram of a 3-bit counter with a DC-driven DPS.

FIG. 13 shows graphs of various signals within the circuit according to the embodiment of FIG. 12.

FIG. 14 shows graphs of various signals within the circuit according to the embodiment of FIG. 12, but with use of unshunted Josephson junctions.

FIG. 15 shows a circuit layout for a T Flip-Flop, which includes shunting resistors.

FIG. 16 shows a circuit layout for a T Flip-Flop, which excludes shunting resistors, demonstrating space optimization with respect to FIG. 15.

FIG. 17 shows a block diagram of the digital phase source technology, in an AC biased digital phase source (DPS) provides quantized energy replenishment of the data processing circuit (DPU).

FIG. 18 shows graphs of various signals within the circuit according to the embodiment of FIG. 17.

FIG. 19 shows a circuit implementing a 2-bit counter with AC driven DPS according to the embodiment of FIG. 17.

FIG. 20 shows graphs of various signals within the circuit according to the embodiment of FIG. 19.

FIG. 21 shows a block diagram of the digital phase source technology with unshunted Josephson junctions, in an AC biased digital phase source (DPS) which provides quantized energy replenishment of the data processing circuit (DPU).

FIG. 22 shows graphs of various signals within the circuit according to the embodiment of FIG. 19.

FIG. 23 shows a block diagram of the digital phase source technology with fully unshunted Josephson junctions, in an AC biased digital phase source (DPS) which provides quantized energy replenishment of the data processing circuit (DPU).

FIG. 24 shows graphs of various signals within the circuit according to the embodiment of FIG. 23.

FIG. 25 shows a circuit layout for an AC biased T Flip-Flop having shunting resistors.

FIG. 26 shows a circuit layout for an AC biased T Flip-Flop, which excludes all shunting resistors.

### DETAILED DESCRIPTION OF THE PREFERRED EMBODIMENTS

Superconducting Sustainable Ballistic Fluxon (SSBF) technology is based on two main components: superconducting low-loss data processing circuitry capable of ballistic processing of data fluxons, and digital phase sources enabling sustainable ballistic fluxon processing by quantized replenishment of fluxon energy.

### Quantized Biasing—Digital Phase Source

There is no direct feeding of the data processing circuits by an external source. The external sources are analog-either current or voltage sources, AC or DC. The data processing circuits (DPC) are connected only to digital phase source (DPS), which provides a discrete DC bias current to the DPC. This bias exists only if there is a phase difference between DPS and the DPC. This phase difference is quantized: 2π and can be turned on or turned off by an SFQ (fluxon). The DPS is localized, i.e., it serves only one data processing circuit tap. This means that its energy is not shared with other circuits and its amount is not affected by scaling. DPS provides always the same amount of biasing irrespective of an external source. In other embodiments, these constraints are relaxed.

In turn, the DPS is connected to the external sources. This source can be DC or AC types. In the DC case, the DC current is pre-biasing the DPS, while incoming clock SFQ is generating a 2π increment at the output of DPS, i.e., this SFQ gets stored in the DPS, so that the 2π increment is held at the output (DPS is armed) until consumed by the data fluxon in the data processing circuit. While DPS is armed, its state is not changeable by clock SFQs, they are passed by without changing the DPS state. The power is dissipated only in DPS: P=F_{clk} Φ₀ I_{DPS}, where F_{clk} is a frequency of clock SFQ, I_{DPS} is a DC pre-bias of DPS.

In the AC case, the DPS is armed (SFQ is stored in the DPS) by a single-phase AC source. Once the DPS is armed, the AC does not affect the DSP state until this stored SFQ is consumed by the data fluxon. The external power is used for the DPS arming event, i.e., P˜F_{data} Φ₀ Ic, where F_{data} is average frequency of data fluxons, I_{c} is critical current of input JJ in DPS. Consequently, if data is not present, the power is not dissipated.

### 2. Data Processing Circuit—Ballistic Fluxon Data Processing

Data processing circuits do not consume any energy directly supplied by an external source. It uses the energy stored in DPS and provided only when needed (when the data fluxon arrives and needs energy replenishment). Once energy is replenished by consuming the fluxon stored in the DPS, the phase balance is restored (equalized) and bias current vanishes. There are several important consequences of this approach:

This makes the data processing circuit completely unbiased and refractory to any noise and interference. Consequently, it can be implemented with smaller junctions and exhibit large parameter margins.

Another important consequence of the unbiased junctions is their ability to avoid latching even without shunt resistors. The voltage across an unshunted JJ goes to zero with its bias below certain value, even at high values of McCumber parameter βc. This allows implementation of the data processing circuit using unshunted JJs and, therefore, use substantially denser layout.

Unshunted JJs are less lossy compared to the shunted ones. The SFQs (fluxons) can ballistically propagate through the low loss, bias-free, high-density superconducting gates constructed using standard unshunted Josephson junctions available from any superconducting foundry. The unshunted junctions are also faster than their shunted counterparts, since the junction shunt resistor Rₛₕᵤₙₜ decreases the junction characteristic voltage V_{c}=I_{c}Rₛₕᵤₙₜ and therefore increases the characteristic time constant t=Φ₀/V_{c}, where Φ₀ is magnetic flux quantum Φ₀=h/2e˜2.07 Wb.

To replenish the inevitable loss of fluxon energy during data processing and ensure the sustainable ballistic propagation of data fluxons through the superconducting circuit, the localized digital phase sources (DPS) driven by an external DC or AC source were attached.

The exemplary digital SSBF circuits have already been successfully simulated and optimized with extremely large parameter margins. The SSBF can be a technological basis for the implementation of different logic families and architectures: synchronous, asynchronous, clockless, temporal, dual-rail, etc. While benefiting from the future advanced fabrication processes, SSBF circuits can be implemented using any existing fabrication process. The first SSBF circuits have been laid out and are being fabricated using the proven SFQ-C5SL niobium fabrication process [16] at SEEQC. These circuits are designed for operation near 4 K, although similar circuits optimized for other operating temperatures should show similar behavior. These circuits are expected to function at the same high speeds (greater than 10 GHZ) as more conventional RSFQ circuits.

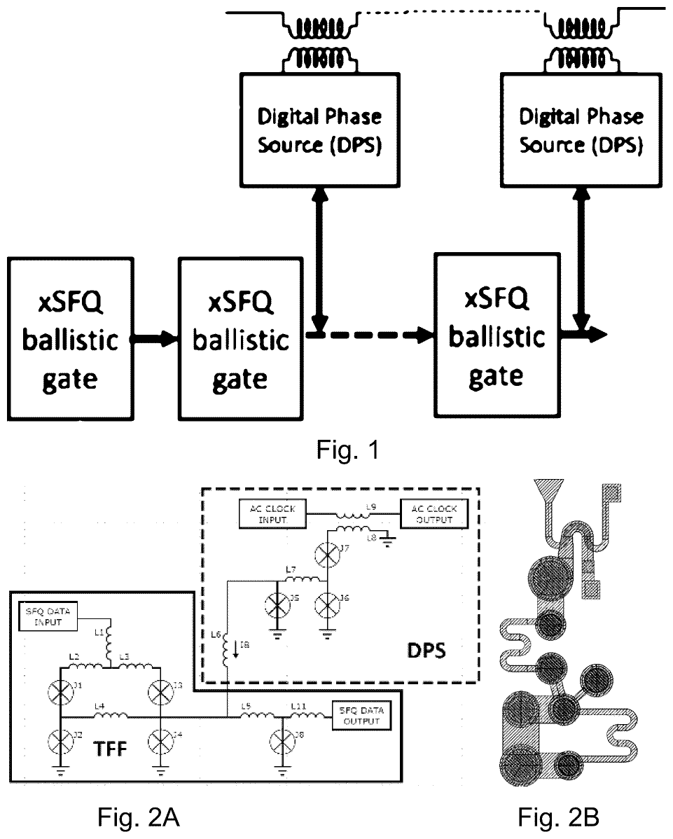

FIG. 1 shows a block diagram of an SSBF circuit showing the injection of energy from DPS between ballistic bias-free logic gates. The DPS cells are inserted only where needed.

FIG. 2A shows an example of the optimized SSBF TFF with the DPS to replenish the energy of the output fluxon, the optimized circuit schematics with margins exceeding +30-40% for all parameters. Circles indicate unshunted JJs;

FIG. 2B shows an example of the optimized SSBF TFF with the DPS to replenish the energy of the output fluxon of FIG. 2A, a micrograph of the fabricated SSBF circuit using SEEQC's SFQ-C5SL process.

The utilization of quantized energy is a key factor enabling the ballistic propagation of data and thereby obviating the necessity for damping in the JJs, making them unshunted. The ballistic nature of propagation keeps the number of DPS modules per circuit to a minimum, and the elimination of shunt resistors contributes significantly to enhanced integration density (FIG. 2B). Additionally, unshunted JJs facilitate the use of narrower transmission lines with higher impedance, which can be further compacted using a projected high-capacitance dielectric layer; as well as future fabrication processes, including π-JJs and multiple JJ layers, have the potential to further augment integration density.

An implementation of a toggle flip-flop based on SSBF is illustrated in FIGS. 2A and 2B, with the restoration of its output fluxon energy achieved through an integrated DPS. Simulations and parameter optimizations achieve margins surpassing +40% for the majority of parameters, with no margin falling significantly below +30% for the entire parameter set. The most profound impact is to be achieved when xSFQ logic is implemented with SSBF technology [17], using the xSFQ gate set (LA and FA), since both are based on the area-compact Muller-C element [12]. The simulations showed that multiple SSBF-based xSFQ gates can be in series with a single DPS cell as shown in FIG. 1. This unambiguously indicates the potential for highly dense and hardware-efficient logic fabric.

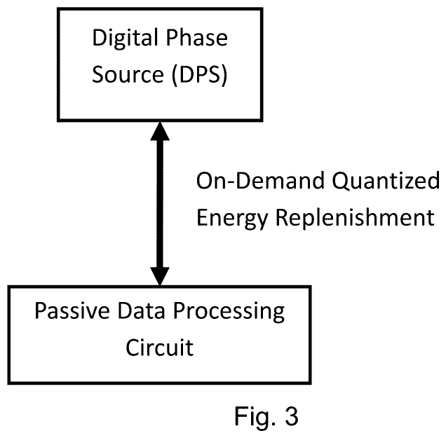

FIG. 3 shows a block diagram of the digital phase source technology, in which a DC biased digital phase source (DPS), a D Flip-Flop, provides quantized energy replenishment of the data processing circuit (DPU), in this case a T Flip-Flop, which may otherwise be passive, when there is a phase difference, and otherwise has low or no quiescent power draw. The current I_{B} flows only of there is a phase difference between the DPS and the DPU. The phase difference is determined by a stored SFQ.

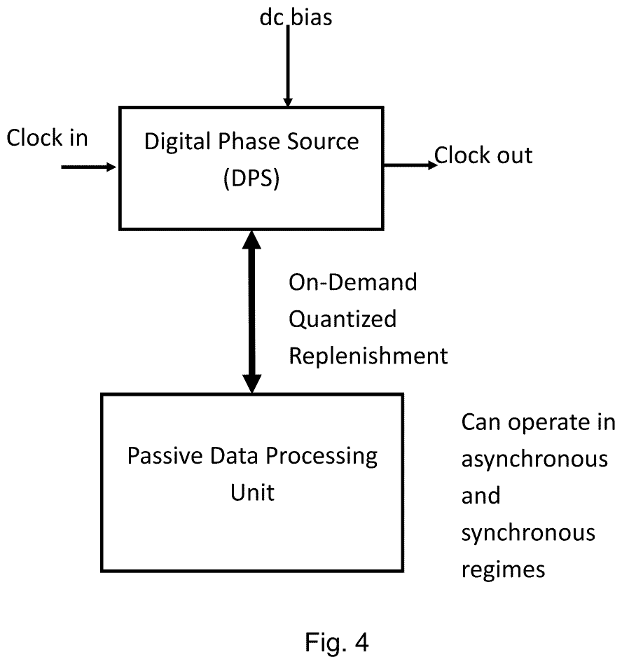

FIG. 4 shows a DC biased digital phase source (DPS), which receives a clock, which is passed to a subsequent circuit, and a DC bias, and produces an on-demand quantized replenishment for a passive data processing unit (DPU) dependent on a status of the DPU, which can operate synchronously or asynchronously. In alternate embodiments, the clock SFQ may come first or the data SFQ may come first. In the later case, the DPU stores the energy represented by the received data until replenished, or transfers the energy to the DPS if supported.

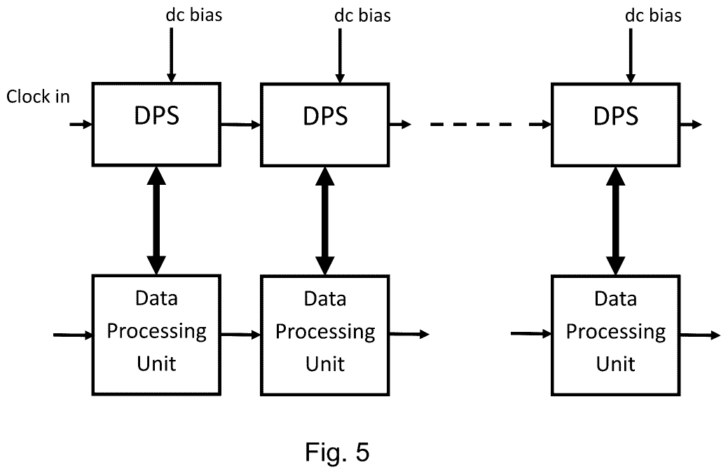

FIG. 5 shows a series of DC biased digital phase sources (DPS) which propagate a clock signal in a chain, with the clock as the DC bias source, and each DPS providing power for a data processing unit (DPU) in a serial data processing chain.

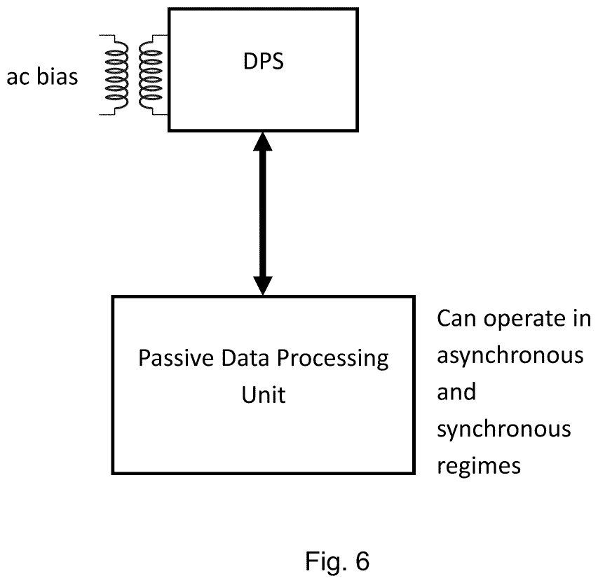

FIG. 6 shows an AC biased digital phase source (DPS), which receives an AC bias oscillating signal and produces an on-demand quantized replenishment for a passive data processing unit (DPU) dependent on a status of the DPU, which can operate synchronously or asynchronously. In alternate embodiments, the clock SFQ may come first or the data SFQ may come first. In the later case, the DPU stores the energy represented by the received data until replenished, or transfers the energy to the DPS if supported.

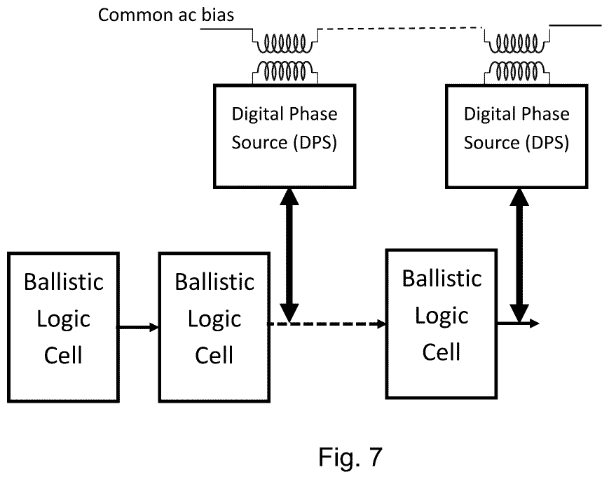

FIG. 7 shows a series of AC biased digital phase sources (DPS), and each DPS providing power for a ballistic logic cell in a serial data processing chain.

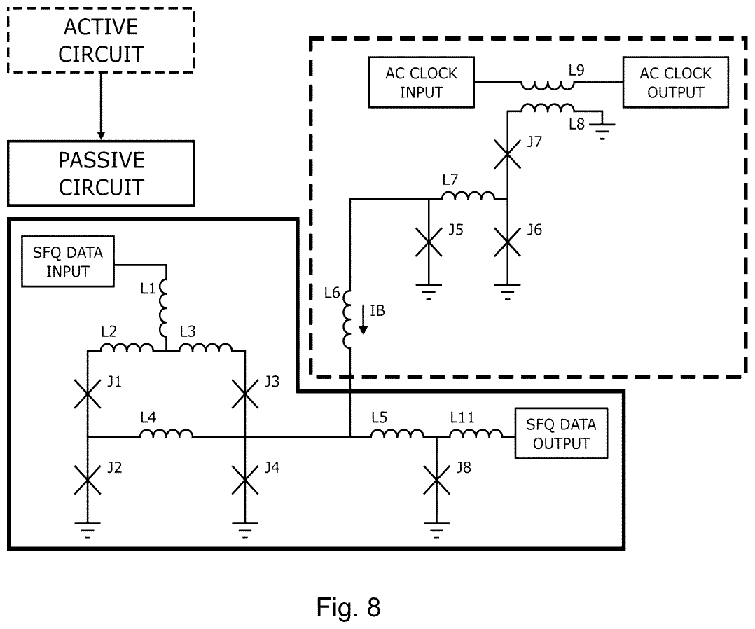

FIG. 8 shows a typical circuit for an AC-biased digital phase source (DPS) connected to a data processing unit (DPU), in which the AC signal provides replenishment for a single flux quantum from the DPS portion of the circuit (upper right), to a DPU portion of the circuit (lower left).

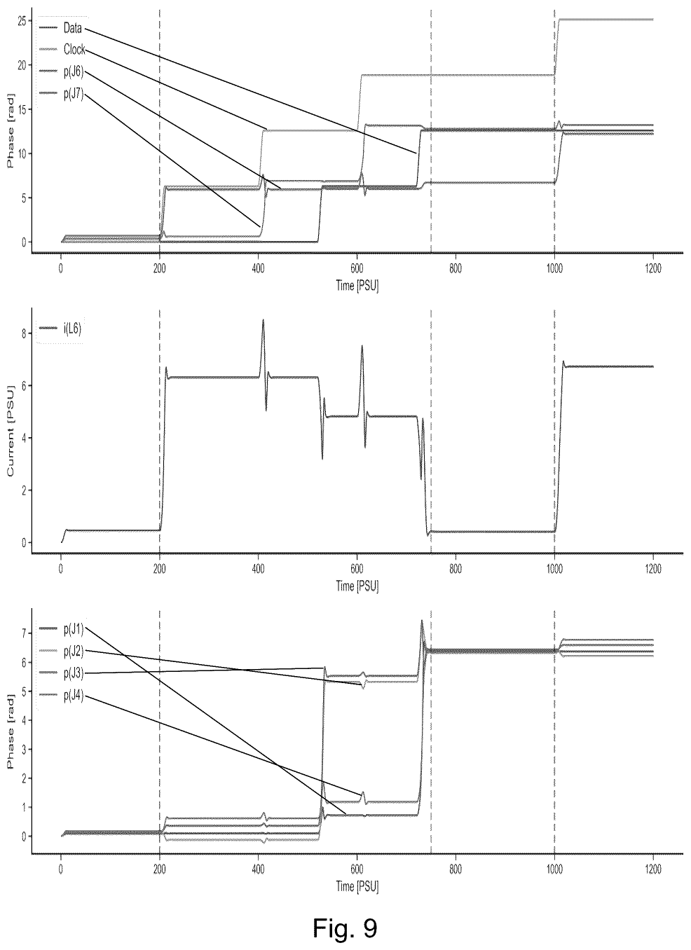

FIG. 9 shows traces of simulated signals of the circuit according to FIG. 8. Margins for most parameters are quite large, at least 40%.

TABLE 1

Margins for esfq_sync_tff_aux.i1 [40.00%, 40.00%]
Margins for esfq_sync_tff_aux.j1[40.00%, 34.07%]
Margins for esfq_sync_tff_aux.j2 [40.00%, 40.00%]
Margins for esfq_sync_tff_aux.j3 [40.00%, 40.00%]
Margins for esfq_sync_tff_aux.j4 [40.00%, 40.00%]
Margins for esfq_sync_tff_aux.j5 [40.00%, 40.00%]
Margins for esfq_sync_tff_aux.j6 [40.00%, 40.00%]
Margins for esfq_sync_tff_aux.j7 [28.13%, 29.50%]
Margins for esfq_sync_tff_aux.j8 [40.00%, 40.00%]
Margins for esfq_sync_tff_aux.l9 [40.00%, 40.00%]
Margins for esfq_sync_tff_aux.l1 [40.00%, 40.00%]
Margins for esfq_sync_tff_aux.l2 [40.00%, 40.00%]
Margins for esfq_sync_tff_aux.l3 [40.00%, 40.00%]
Margins for esfq_sync_tff_aux.l4 [40.00%, 40.00%]
Margins for esfq_sync_tff_aux.l5 [40.00%, 40.00%]
Margins for esfq_sync_tff_aux.l6 [40.00%, 40.00%]
Margins for esfq_sync_tff_aux.l7 [36.85%, 40.00%]
Margins for esfq_sync_tff_aux.l8 [40.00%, 40.00%]
Margins for esfq_sync_tff_aux.l9 [40.00%, 40.00%]
Margins for esfq_sync_tff_aux.l10 [40.00%, 40.00%]
Margins for esfq_sync_tff_aux.xi [40.00%, 40.00%]
Margins for esfq_sync_tff_aux.xj [29.50%, 40.00%]
Margins for esfq_sync_tff_aux.xl [40.00%, 40.00%]
Margins for esfq_sync_tff_aux.xr [40.00%, 40.00%]

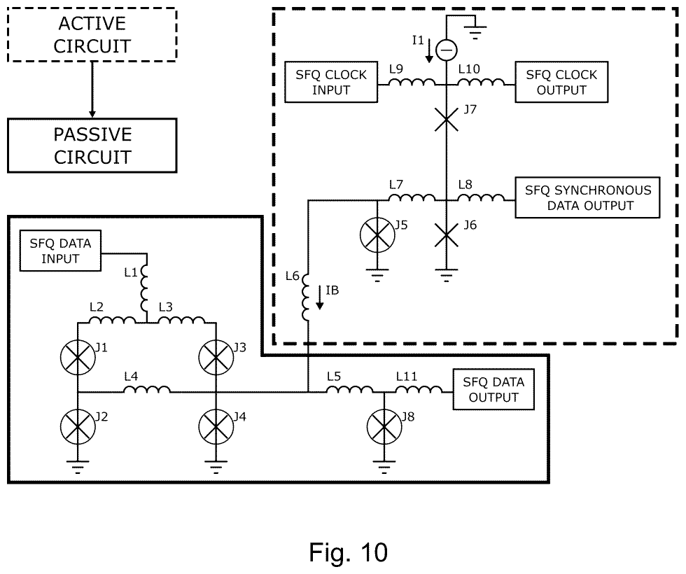

FIG. 10 shows an alternate embodiment of the circuit according to FIG. 3, in which circled Josephson junctions are unshunted.

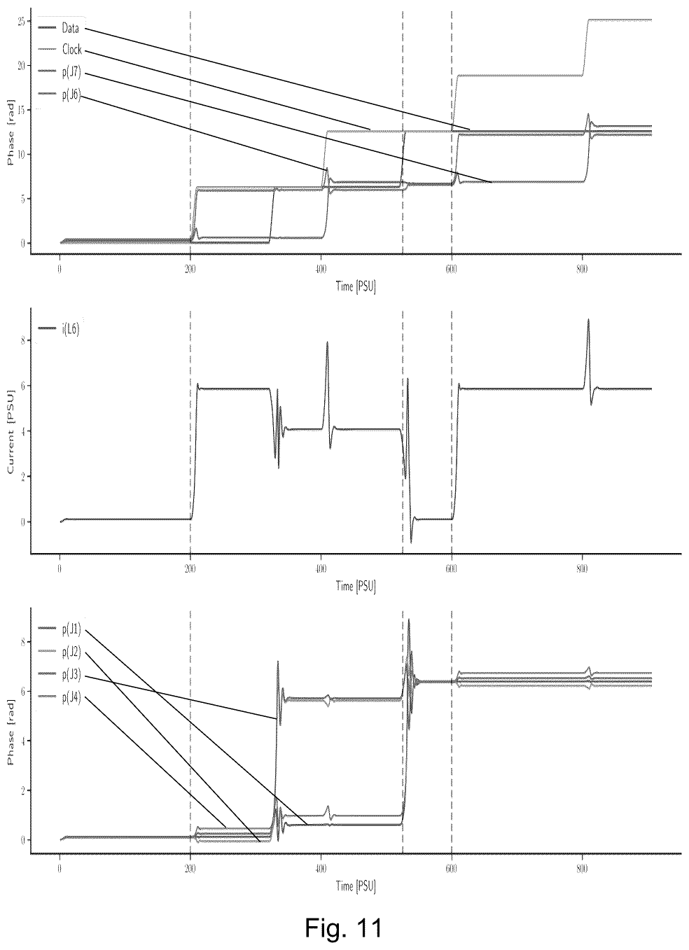

FIG. 11 shows graphs of various signals within the circuit according to the embodiment of FIG. 10, and which shows ringing with respect to comparable FIG. 9.

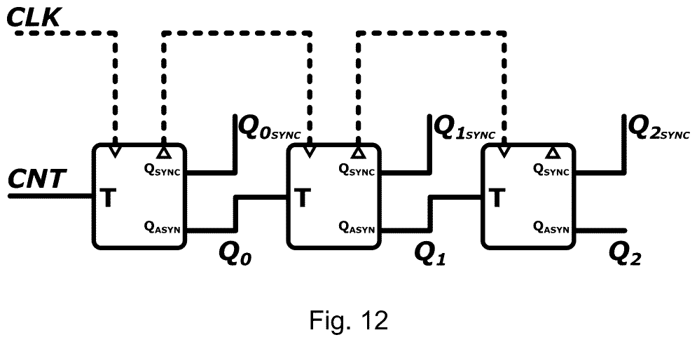

FIG. 12 shows a block diagram of a 3-bit counter with a DC-driven DPS.

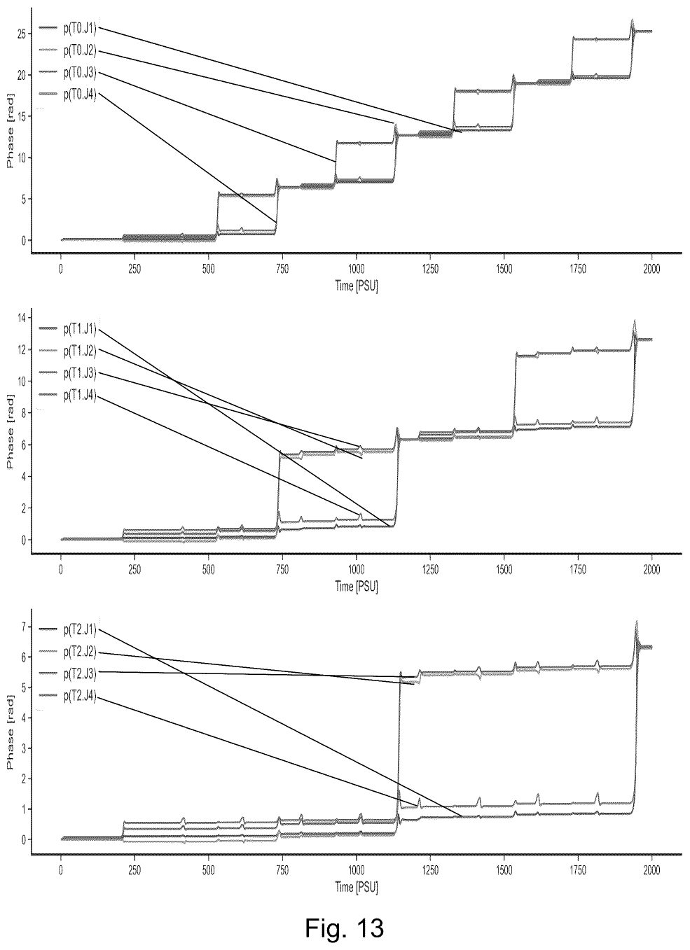

FIG. 13 shows graphs of various signals within the circuit according to the embodiment of FIG. 12.

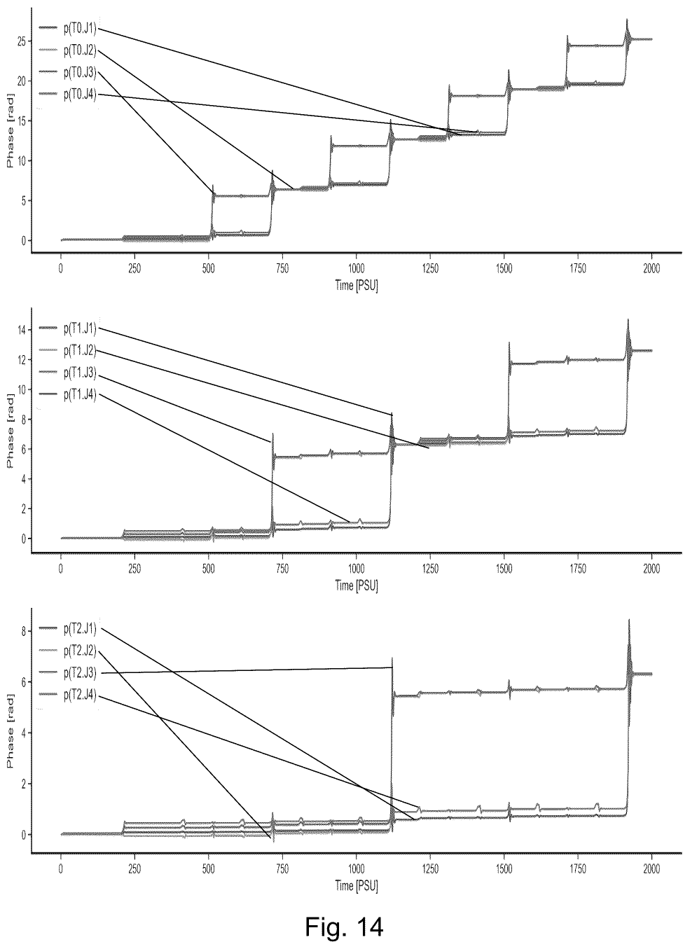

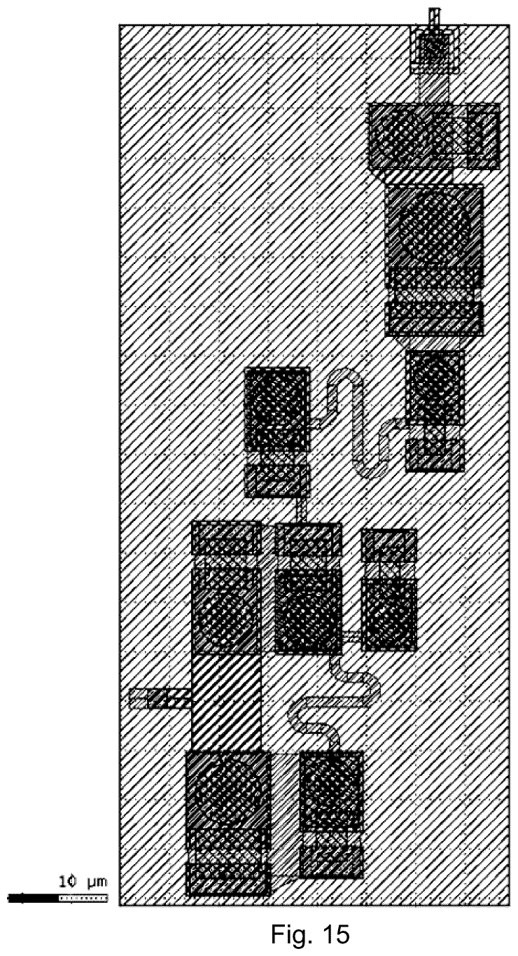

FIG. 14 shows graphs of various signals within the circuit according to the embodiment of FIG. 12, but with use of unshunted Josephson junctions.

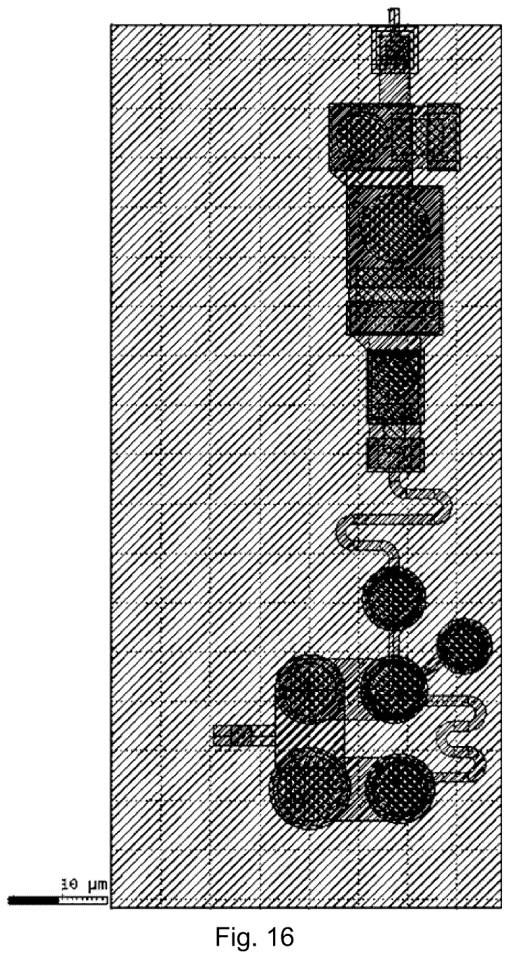

FIG. 15 shows a circuit layout for a T Flip-Flop, which includes shunting resistors.

FIG. 16 shows a circuit layout for a T Flip-Flop, which excludes shunting resistors, demonstrating space optimization with respect to FIG. 15.

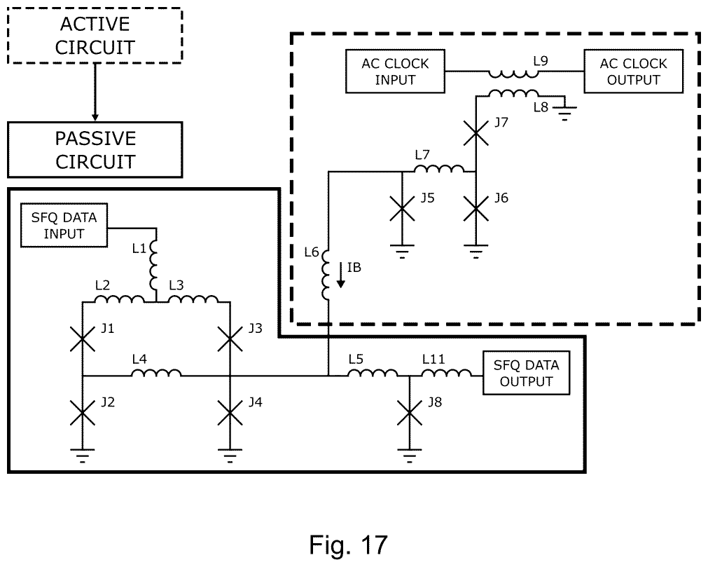

FIG. 17 shows a block diagram of the digital phase source technology, in an AC biased digital phase source (DPS), a D Flip-Flop, provides quantized energy replenishment of the data processing circuit (DPU), in this case a T Flip-Flop, which may otherwise be passive, when there is a phase difference, and otherwise has low or no quiescent power draw. The current I_{B} flows only if there is a phase difference between the DPS and the DPU. The phase difference is determined by a stored SFQ.

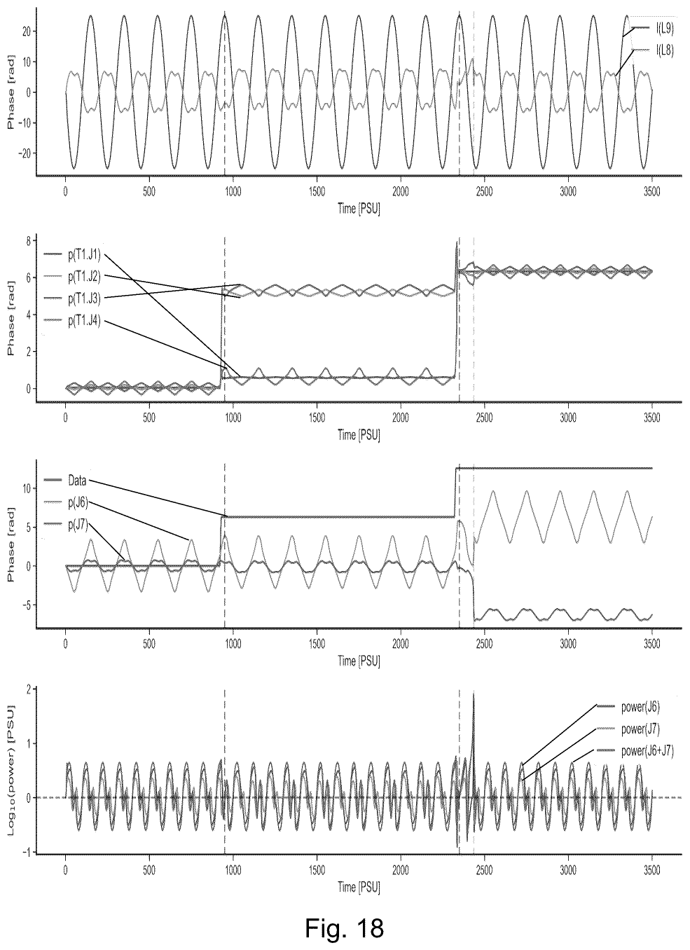

FIG. 18 shows graphs of various signals within the circuit according to the embodiment of FIG. 17. Margins for most parameters are >40%:

TABLE 2

Margins for ac_tff_clocked_esfq.j1 [36.85%, 32.17%]
Margins for ac_tff_clocked_esfq.j2 [40.00%, 40.00%]
Margins for ac_tff_clocked_esfq.j3 [40.00%, 40.00%]
Margins for ac_tff_clocked_esfq.j4 [40.00%, 40.00%]
Margins for ac_tff_clocked_esfq.j5 [40.00%, 40.00%]
Margins for ac_tff_clocked_esfq.j6 [40.00%, 40.00%]
Margins for ac_tff_clocked_esfq.j7 [28.13%, 28.13%]
Margins for ac_tff_clocked_esfq.j8 [40.00%, 40.00%]
Margins for ac_tff_clocked_esfq.l1 [40.00%, 40.00%]
Margins for ac_tff_clocked_esfq.l2 [40.00%, 40.00%]
Margins for ac_tff_clocked_esfq.l3 [40.00%, 40.00%]
Margins for ac_tff_clocked_esfq.l4 [34.07%, 40.00%]
Margins for ac_tff_clocked_esfq.l5 [40.00%, 40.00%]
Margins for ac_tff_clocked_esfq.l6 [40.00%, 40.00%]
Margins for ac_tff_clocked_esfq.l7 [32.17%, 40.00%]
Margins for ac_tff_clocked_esfq.l8 [40.00%, 40.00%]
Margins for ac_tff_clocked_esfq.l9 [40.00%, 40.00%]
Margins for ac_tff_clocked_esfq.lm [34.07%, 32.17%]
Margins for ac_tff_clocked_esfq.xi [40.00%, 40.00%]
Margins for ac_tff_clocked_esfq.xj [30.58%, 30.58%]
Margins for ac_tff_clocked_esfq.xl [40.00%, 40.00%]
Margins for ac_tff_clocked_esfq.xr [40.00%, 40.00%]

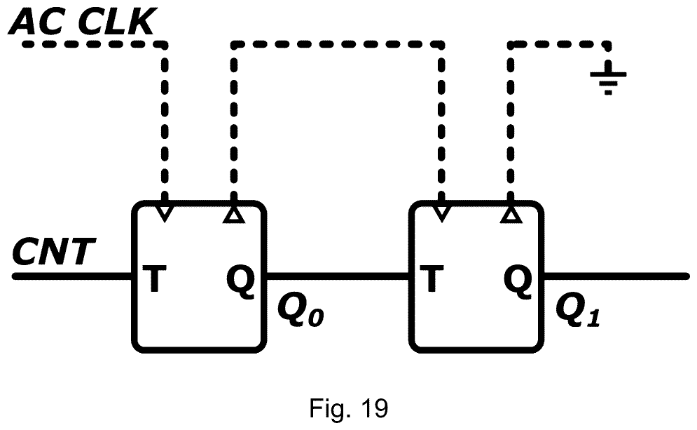

FIG. 19 shows a circuit implementing a 2-bit counter with AC driven DPS according to the embodiment of FIG. 17.

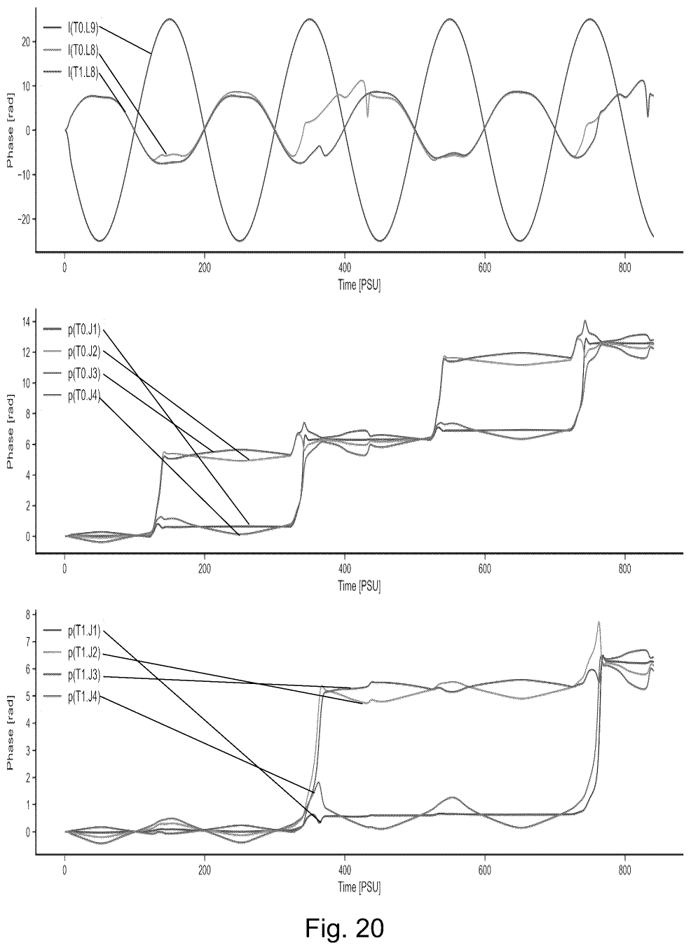

FIG. 20 shows graphs of various signals within the circuit according to the embodiment of FIG. 19.

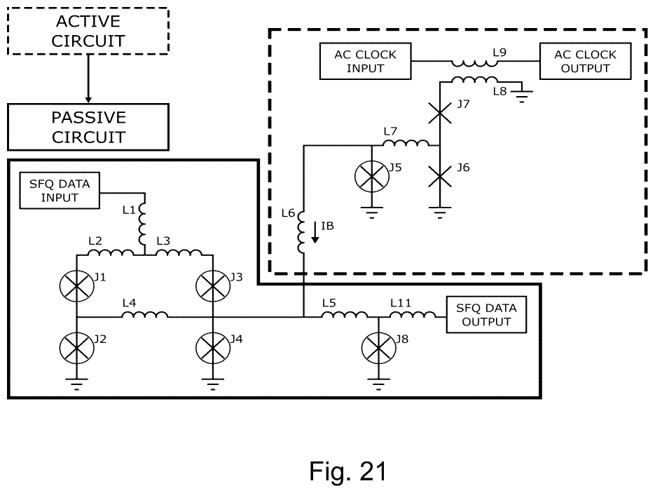

FIG. 21 shows a block diagram of the digital phase source technology with unshunted Josephson junctions, in an AC biased digital phase source (DPS), a D Flip-Flop, provides quantized energy replenishment of the data processing circuit (DPU), in this case a T Flip-Flop, which may otherwise be passive, when there is a phase difference, and otherwise has low or no quiescent power draw. The current I_{B} flows only if there is a phase difference between the DPS and the DPU. The phase difference is determined by a stored SFQ.

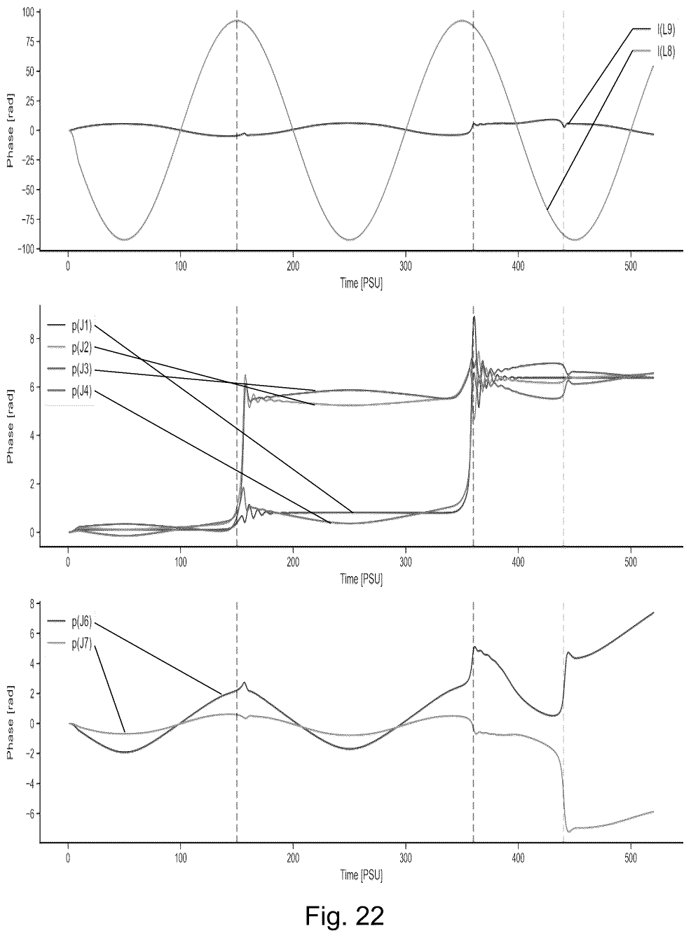

FIG. 22 shows graphs of various signals within the circuit according to the embodiment of FIG. 19. Margins for most parameters are >40%:

TABLE 3

Margins for ac_tff_clocked_esfq.j1 [39.34%, 25.36%]
Margins for ac_tff_clocked_esfq.j2 [40.00%, 40.00%]
Margins for ac_tff_clocked_esfq.j3 [40.00%, 30.58%]
Margins for ac_tff_clocked_esfq.j4 [40.00%, 40.00%]
Margins for ac_tff_clocked_esfq.j5 [40.00%, 40.00%]
Margins for ac_tff_clocked_esfq.j6 [40.00%, 40.00%]
Margins for ac_tff_clocked_esfq.j7 [32.17%, 28.13%]
Margins for ac_tff_clocked_esfq.j8 [40.00%, 40.00%]
Margins for ac_tff_clocked_esfq.l1 [40.00%, 40.00%]
Margins for ac_tff_clocked_esfq.l2 [40.00%, 40.00%]
Margins for ac_tff_clocked_esfq.l3 [40.00%, 40.00%]
Margins for ac_tff_clocked_esfq.l4 [38.24%, 40.00%]
Margins for ac_tff_clocked_esfq.l5 [40.00%, 40.00%]
Margins for ac_tff_clocked_esfq.l6 [40.00%, 40.00%]
Margins for ac_tff_clocked_esfq.l7 [40.00%, 40.00%]
Margins for ac_tff_clocked_esfq.l8 [40.00%, 40.00%]
Margins for ac_tff_clocked_esfq.l9 [40.00%, 40.00%]
Margins for ac_tff_clocked_esfq.lm [29.50%, 13.51%]
Margins for ac_tff_clocked_esfq.xi [40.00%, 40.00%]
Margins for ac_tff_clocked_esfq.xj [35.46%, 30.58%]
Margins for ac_tff_clocked_esfq.xl [40.00%, 40.00%]
Margins for ac_tff_clocked_esfq.xr [40.00%, 40.00%]

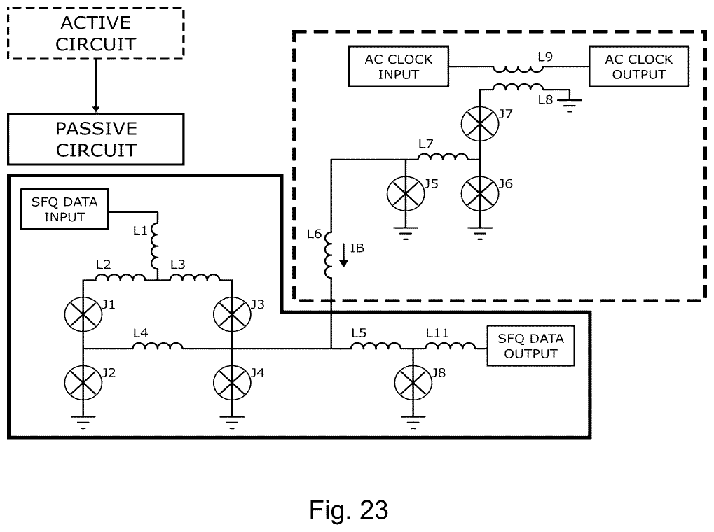

FIG. 23 shows a block diagram of the digital phase source technology with fully unshunted Josephson junctions, in an AC biased digital phase source (DPS), a D Flip-Flop, provides quantized energy replenishment of the data processing circuit (DPU), in this case a T Flip-Flop, which may otherwise be passive, when there is a phase difference, and otherwise has low or no quiescent power draw. The current I_{B} flows only if there is a phase difference between the DPS and the DPU. The phase difference is determined by a stored SFQ.

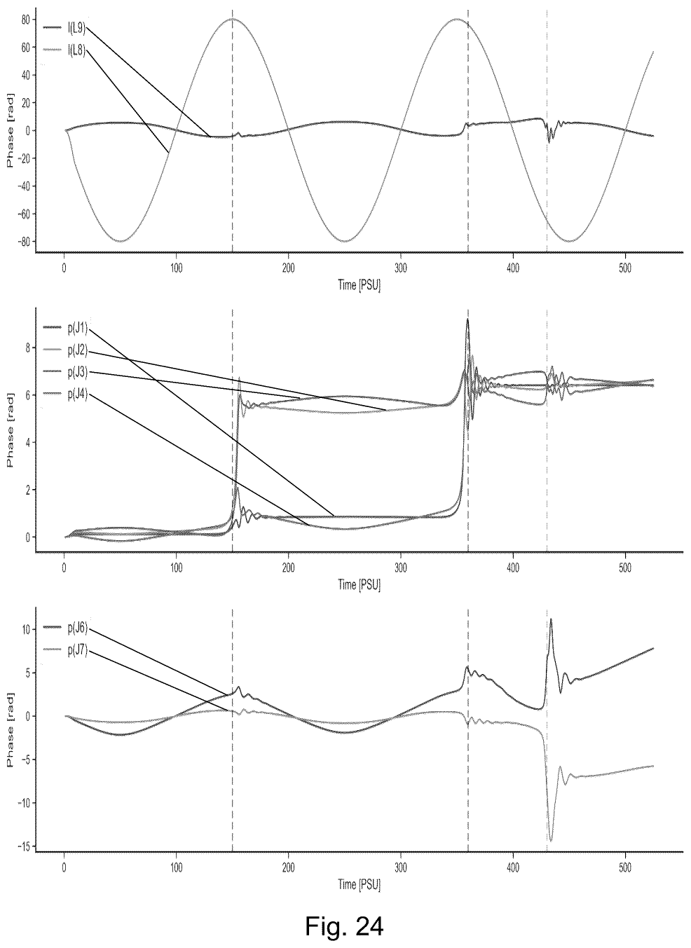

FIG. 24 shows graphs of various signals within the circuit according to the embodiment of FIG. 23. Margins for most parameters are >40%:

TABLE 4

Margins for ac_tff_clocked_esfq.j1 [38.24%, 34.07%]
Margins for ac_tff_clocked_esfq.j2 [40.00%, 40.00%]
Margins for ac_tff_clocked_esfq.j3 [32.17%, 35.46%]
Margins for ac_tff_clocked_esfq.j4 [40.00%, 40.00%]
Margins for ac_tff_clocked_esfq.j5 [40.00%, 40.00%]
Margins for ac_tff_clocked_esfq.j6 [32.17%, 35.46%]
Margins for ac_tff_clocked_esfq.j7 [40.00%, 34.07%]
Margins for ac_tff_clocked_esfq.j8 [40.00%, 40.00%]
Margins for ac_tff_clocked_esfq.l1 [40.00%, 40.00%]
Margins for ac_tff_clocked_esfq.l2 [40.00%, 40.00%]
Margins for ac_tff_clocked_esfq.l3 [40.00%, 40.00%]
Margins for ac_tff_clocked_esfq.l4 [38.24%, 40.00%]
Margins for ac_tff_clocked_esfq.l5 [40.00%, 40.00%]
Margins for ac_tff_clocked_esfq.l6 [40.00%, 40.00%]
Margins for ac_tff_clocked_esfq.l7 [40.00%, 40.00%]
Margins for ac_tff_clocked_esfq.l8 [40.00%, 40.00%]
Margins for ac_tff_clocked_esfq.l9 [40.00%, 40.00%]
Margins for ac_tff_clocked_esfq.lm [15.96%, 19.43%]
Margins for ac_tff_clocked_esfq.xi [40.00%, 40.00%]
Margins for ac_tff_clocked_esfq.xj [34.07%, 35.46%]
Margins for ac_tff_clocked_esfq.xl [40.00%, 40.00%]
Margins for ac_tff_clocked_esfq.xr [40.00%, 40.00%]

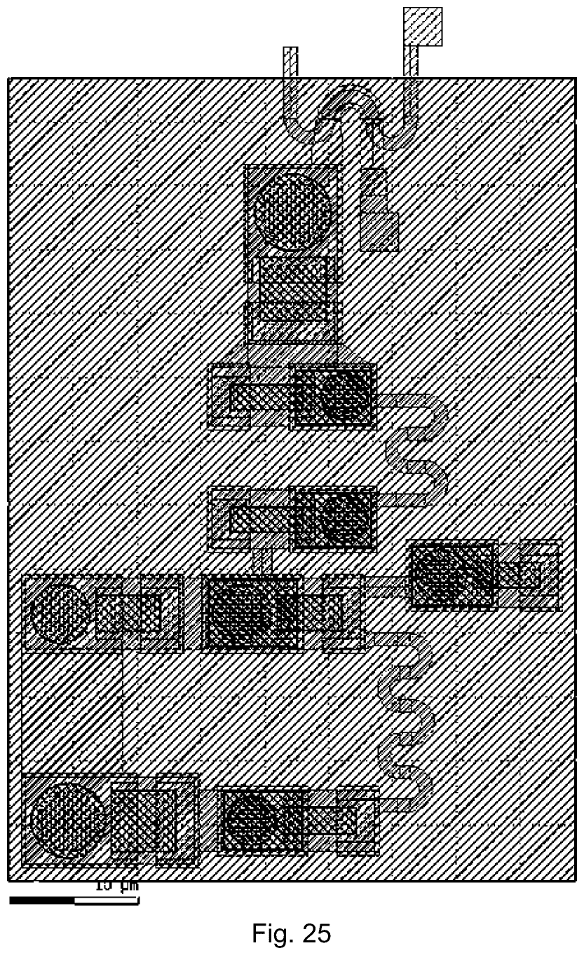

FIG. 25 shows a circuit layout for an AC biased T Flip-Flop having shunting resistors.

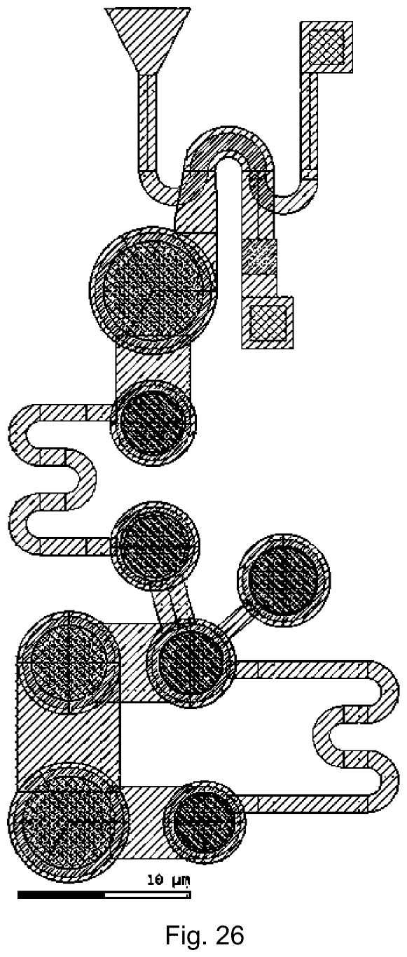

FIG. 26 shows a circuit layout for an AC biased T Flip-Flop, which excludes all shunting resistors.

Taken together, the simulations show that there is no degradation in circuit margins by replacing conventional shunted junctions with compact unshunted junctions, enabling more compact layouts as well as reduced power dissipation.

SSBF is the world's first ballistic processing circuit technology realizing sustainable propagation of ballistic data throughout the processing circuitry. This makes SSBF capable of scaling to the practical circuit sizes in any electronic technology including SCE. Due to its high energy efficiency, SSBF can also be considered for the basis for reversible computing architectures.

SSBF solves many problems existing today with SCE circuits preventing their widespread use. As described above, SSBF circuits have higher parameter margins, higher immunity to noise, since the logic cell are unbiased most of the time and refractory to environment. The biasing (energy replenishment) is generated locally and not dependent on neighboring cells leading to no bias margin degradation due with scaling. Although SSBF can be a technology basis to implement different SFQ logics, it fits particularly well with xSFQ logic. High uniformity of the xSFQ logic fabric based on essentially a single type of gate structure (Muller-C element) typically assures higher fabrication yield characteristic for the highly regular layouts.

The SSBF zero static power dissipation, minimized dynamic power dissipation of ballistic circuits, and the ballistic propagation of fluxons yield substantial improvements in terms of energy per instruction.

SSBF's quantized biasing effectively addresses the fundamental electrical limitations found in existing power schemes.

The disclosure has been described with reference to various specific embodiments and techniques. However, many variations and modifications are possible while remaining within the scope of the disclosure.

The claims herein are intended to be interpreted as encompassing all feasible combinations and permutations of the claim elements. A singular element is intended to encompass one or more of that element. All references cited herein are expressly incorporated herein by reference. The word “comprising” is intended to encompass at least the enumerated elements, and feasible additional elements not inconsistent with the explicit recited elements.

1. A superconducting digital phase source for a superconducting digital circuit, comprising:
a storage circuit configured to store a fluxon or single flux quantum (SFQ) based on energy from a power source; and
a digital power output port configured to generate a phase output at a specified phase value from the stored fluxon or single flux quantum (SFQ).

2. The superconducting digital phase source of claim 1, wherein the storage circuit comprises a plurality of Josephson junctions, wherein at least one of the Josephson junctions is underdamped.

3. The superconducting digital phase source of claim 1, wherein the power source comprises a clock input and the storage circuit comprises D-flip-flop.

4. The superconducting digital phase source of claim 1, wherein the digital power output port is configured to supply the phase output at the specified phase value to a data processing circuit comprising a plurality of Josephson junctions, and wherein at least one of the junctions is undamped or underdamped.

5. The superconducting digital phase source of claim 4, wherein the data processing circuit comprises an asynchronous xSFQ logic circuit or DSFQ logic circuit.

6. The superconducting digital phase source of claim 4, wherein the data processing circuit comprises a synchronous the RSFQ, ERSFQ, eSFQ, HFQ, RQL, or PCL logic circuit.

7. The superconducting digital phase source of claim 1, further comprising a passive data processing circuit, wherein the digital power output port is configured to supply the phase output at the specified phase value to the passive data processing circuit as a sole energy source to support information propagation.

8. The superconducting digital phase source of claim 7, wherein the phase output supplies energy to the passive data processing circuit to replenish energy transmitted to support information propagation.

9. The superconducting digital phase source of claim 1, further comprising a data processing circuit configured to store a fluxon or single flux quantum (SFQ) at a first phase, and to communicate the fluxon or single flux quantum (SFQ) as information to thereby enter a second phase, wherein the phase output at the specified phase value is configured to generate the phase output to selectively supply the fluxon or single flux quantum (SFQ) to the data processing circuit in the second phase to return the data processing circuit to the first phase, and to generate no fluxon or single flux quantum (SFQ) when the data processing circuit is in the first phase.

10. The superconducting digital phase source according to claim 1, wherein the storage circuit has a phase, and is configured to transfer the fluxon or single flux quantum (SFQ) to the digital power output port as the phase output when a phase difference is present at the digital power output port, else continue to store the fluxon or single flux quantum (SFQ).

11. The superconducting digital phase source according to claim 1, wherein the storage circuit has a capacity to store a single fluxon or single flux quantum (SFQ), and the generated phase output at the specified phase value is dependent on a first phase based on the fluxon or single flux quantum (SFQ) stored in the storage circuit and a second phase dependent on a state of a circuit present at the digital power output port.

12. The superconducting digital phase source according to claim 1, wherein the storage circuit has a capacity to store a plurality of fluxons or single flux quanta (SFQ), and the generated phase output at the specified phase value is dependent on a first phase based on a number of the fluxon or single flux quantum (SFQ) stored in the storage circuit and a second phase dependent on a multilevel quantized state of a circuit present at the digital power output port.

13. The superconducting digital phase source according to claim 1, wherein the power source receives sufficient power only to replenish power transferred through the digital power output port as the generated phase output.

14. The superconducting digital phase source according to claim 1, further comprising:
a first data processing circuit configured to receive the phase output and a first fluxon or single flux quantum (SFQ) information signal as sole sources of power for a second fluxon or single flux quantum (SFQ) information signal produced by the first data processing circuit; and
a second data processing circuit configured to receive the second fluxon or single flux quantum (SFQ) information signal as a sole source of power for a third fluxon or single flux quantum (SFQ) information signal produced by the second data processing circuit.

15. The superconducting digital logic circuit according to claim 1, further comprising:
a plurality of digital phase sources, each comprising a power input port configured to receive power from a power source, a storage circuit configured to store a fluxon or single flux quantum (SFQ) based on energy from the power input port, and a digital power output port configured to generate a phase output at a specified phase value from the stored fluxon or single flux quantum (SFQ); and
a plurality of data processing circuits, configured to receive a respective phase output from a respective digital phase source, wherein the plurality of data processing circuits are configured for serial processing of digital data.

16. The superconducting digital logic circuit according to claim 15, wherein a first serially connected data processing circuit receives at least a portion of its operating power from a respective digital phase source, and a second serially connected data processing circuit receives all of its operating power from the first serially connected data processing circuit.

17. The superconducting digital logic circuit according to claim 15, wherein the plurality of data processing circuits each comprise an unshunted, underdamped Josephson junction which produces an oscillating output, and the plurality of data processing circuits produce respective outputs with only insignificant ringing.

18. A superconducting integrated circuit, comprising:
a plurality of passive logic circuits configured for serial processing of digital data, each comprising a plurality of first Josephson junctions, at least one of the plurality of first Josephson junctions being underdamped; and
a plurality of active digital phase sources each comprising a plurality of second Josephson junctions, at least one of the plurality of second Josephson junctions being underdamped, wherein each active digital phase source provides power for a respective passive logic circuit.

19. The superconducting integrated circuit of claim 18, wherein the underdamped first Josephson junctions are fabricated without a shunt resistor and the underdamped second Josephson junctions are fabricated without a shunt resistor.

20. The superconducting integrated circuit of claim 18, wherein the plurality of passive logic circuits are configured to at least one of:
perform quantum error correction;
control a quantum computing system;
read out information from a quantum computing system; and
support operation of a quantum computing system comprising a superconducting qubit, selected from the group consisting of a transmon, a flux qubit, a charge qubit, a phase qubit, and a fluxonium.

21. The superconducting integrated circuit of claim 18, wherein the plurality of passive logic circuits are configured to provide control and readout for an array of superconducting sensors, comprising at least one of SQUIDs, transition edge sensors, superconducting nanowires, kinetic inductance detectors, and superconducting tunnel junction detectors.

22. The superconducting integrated circuit of claim 18, further comprising a plurality of second passive logic circuits configured for serial processing of digital data, each comprising a plurality of third Josephson junctions, at least one of the plurality of third Josephson junctions being underdamped, wherein each second passive logic circuit receives sole operating power from an information signal produced by a respective passive logic circuit.

23. A method of operating a superconducting digital circuit, comprising:
providing a storage circuit configured to store a fluxon or single flux quantum (SFQ); and
a digital power output port configured to generate a phase output at a specified phase value from the stored fluxon or single flux quantum (SFQ);
receiving logic pulses into the storage circuit;
storing power from the logic pulses in the storage circuit as the fluxon or single flux quantum (SFQ); and
generating the phase output at a specified phase value from the stored fluxon or single flux quantum (SFQ).
